(19) United States
(12) Patent Application Publication
(10) Pub. No.: US 2025/0101592 A1
(43) Pub. Date: Mar. 27, 2025

(54) COATING APPARATUS, PROCESS CHAMBER, AND METHOD OF COATING A SUBSTRATE AND SUBSTRATE COATED WITH AT LEAST ONE MATERIAL LAYER

(71) Applicant: MAX-PLANCK-GESELLSCHAFT ZUR FÖRDERUNG DER WISSENSCHAFTEN E.V., Munchen (DE)

(72) Inventors: Wolfgang Braun, Bietigheim-Bissingen (DE); Jochen Mannhart, Boblingen (DE)

(73) Assignee: MAX-PLANCK-GESELLSCHAFT ZUR FÖRDERUNG DER WISSENSCHAFTEN E.V., Munchen (DE)

(21) Appl. No.: 18/922,293

(22) Filed: Oct. 21, 2024

Related U.S. Application Data
(63) Continuation-in-part of application No. 17/290,413, filed on Apr. 30, 2021, now abandoned.

(30) Foreign Application Priority Data
Oct. 31, 2018 (DE) 10 2018 127 262.6

(51) Int. Cl. C23C 16/48; C23C 16/40; C23C 16/458

(52) U.S. Cl. CPC C23C 16/483; C23C 16/40; C23C 16/4583

(57) ABSTRACT

The present invention refers to a coating apparatus for coating a substrate of a substrate material with at least one material layer of a layer material, said coating apparatus comprising a process chamber having a process volume for receiving a substrate holder for arranging the substrate, wherein the substrate holder is arranged in a fixed position in the process volume such that the substrate holder can furthermore be provided rotatable and/or movable essentially in a plane normal to the deposition direction as a whole, wherein the process chamber has a chamber wall for at least substantially completely enclosing the process volume; a gas system connected in a fluid-communicating manner to the process volume for generating a coating atmosphere in the process volume; and a source holder arranged in the process volume and providing at least one source material.

The present invention relates to a coating apparatus for coating a substrate of a substrate material with at least one material layer of a layer material, said coating apparatus comprising a process chamber having a process volume for receiving a substrate holder for arranging the substrate in a fixed position in the process volume such that the substrate holder can furthermore be provided rotatable and/or movable essentially in a plane normal to the deposition direction as a whole, wherein the process chamber has a chamber wall for at least substantially completely enclosing the process volume; a gas system connected in a fluid-communicating manner to the process volume for generating a coating atmosphere in the process volume; and a source holder arranged in the process volume and having at least one source material, wherein each of the at least one source materials is provided as a pure chemical element, said coating apparatus further comprising a source heating laser, wherein the source heating laser is configured to provide a continuous or at least substantially continuous separate beam of laser light for each of the at least one elemental source materials and the process chamber has a coupling-in apparatus having at least one coupling-in section in the chamber wall for conducting the separate beams of laser light of the source heating laser into the process volume for thermally evaporating and/or sublimating each of the elemental source materials below a plasma generation threshold, wherein the source holder and the substrate holder are further arranged relative to one another such that thermally evaporated and/or sublimated source material can be deposited on the substrate for an at least partial formation of the layer material of the material layer. The present invention also relates to a process chamber for a coating apparatus for coating a substrate of a substrate material with at least one material layer of a layer material. The present invention further relates to a method of coating a substrate of a substrate material with at least one material layer of a layer material in a coating apparatus. A further aspect of the invention relates to a substrate coated with at least one material layer, comprising the substrate of substrate material that is coated with at least one material layer comprising a layer material.

A coating of a substrate of a substrate material with a material layer of a layer material is generally known in the prior art. For example, such coating processes can be used in the manufacture of integrated circuits. Other electrical or electronic components, such as data storage, sensor elements and solar cells, can also be implemented using such coating processes in coating apparatus. Furthermore, further products, such as mirror and/or beam splitters for use in laser technology, can be produced using a coating apparatus or a coating process.

Known methods of coating a substrate in accordance with the prior art, which can be carried out in coating apparatus, are for example MBE (molecular beam expitaxy) and PLD (pulsed laser deposition). These different methods each have specific advantages and disadvantages.

For example, a major advantage of MBE is that a high stoichiometric control of the material layer produced and in particular of its layer material can be provided. Thus, in MBE, even material layers can, for example, be produced in which the layer material has a modulated doping, that is a doping that in particular varies over the layer thickness. A high purity of the material layers produced is also a property of MBE. In MBE, one or more source materials are usually thermally evaporated and/or sublimated by an electric heating and are deposited on a substrate. Furthermore, a high scalability from small to very large substrate areas can be provided in MBE by an increase or a decrease of the surface of the source materials used for evaporation and/or sublimation, for example by a corresponding selection of a source crucible.

However, the use already mentioned above of an electric heating for the thermal evaporation and/or sublimation of the source material also leads to disadvantages in MBE. For example, in particular in a coating atmosphere in which corrosive gases such as oxygen or ozone are present, a pressure limitation of a maximum of 10⁻⁵ mbar, usually even less than 10⁻⁶ mbar, must be observed. This is in particular, for example, due to the fact that the electrical elements present in the process volume, in particular elements of the heating of the source material and/or of the substrate, are corroded and may fail at higher pressures due to the corrosive gases. Furthermore, evaporated and/or sublimated source material is also inevitably deposited at these electrical elements, whereby these elements may likewise be impaired up to a complete destruction of the corresponding electrical component, for example by a short circuit.

In PLD, in contrast, the source material is ablated by extremely short and high-energy laser pulses, that is it is evaporated so quickly that a plasma is formed from the source material. In this respect, pulse durations of 10 ns-50 ns at a repetition frequency of 1-25 per second and energy densities of 10 MW/cm² can, for example, be provided by the lasers used. The clouds of source material produced by the explosive evaporation during the ablation on average have a high kinetic energy of the particles, with the maximum speeds of the explosively evaporated source material particles usually occurring perpendicular to the source surface. Higher pressures in the coating atmosphere in the process volume, in particular up to a range of 1 mbar, are also possible due to these high pressures. These high pressures are often even necessary to slow down the fast source material particles and thus to enable damage to the substrate, on the one hand, and generally to enable a deposition of the source material on the substrate, on the other hand. By avoiding electrical components in the interior of the process volume, further restrictions for the process gas are at least substantially not present in PLD.

However, a very extensive control of the stoichiometry of the growing material layer on the substrate, as is present with MBE, cannot be provided in PLD or can only be provided to a very limited extent. Thus, in PLD, the stoichiometry of the material layer or of the coating material is at least substantially determined by the stoichiometry of the material source used, plus only any reactions with a process gas of the coating atmosphere. For example, the modulation of a doping as part of the layer material described above with respect to the MBE is in particular not possible. It is further disadvantageous that a high laser energy density is required for the above described ablation of the source material by the laser pulses. It can usually only be generated with a small spatial extent at the source material so that a scaling of this method to large areas is not easily possible. In accordance with the prior art, large-area coatings using PLD are usually provided by scanning a surface of the substrate. Coating atmospheres with low pressures, for example less than 10⁻⁴ mbar, are also often disadvantageous for PLD since otherwise the ablated source material cannot be sufficiently slowed down by impacts with the process gas before reaching the substrate.

In summary, with MBE and PLD, two methods are available in the prior art that are each advantageous for specific coating processes. However, certain desired material layers may require a layer material or a layer material composition whose generation is not sufficiently accessible by either method. Thus, many oxides as the layer material, for example, require a corrosive coating atmosphere, preferably having molecular oxygen and/or ozone. To be able to safely produce these oxides, the highest possible pressure of the coating atmosphere, in particular a pressure of, for example, 10⁻³ mbar, is advantageous. However, as described above, this pressure range is not accessible or is only accessible to a very limited extent for MBE in accordance with the prior art. At the same time, these oxides should be produced under a high stoichiometric control, in particular, for example, also with a modulated doping. However, as described above, this is again not possible with PLD that could be carried out in the correspondingly matching pressure range. The same applies to nitrides or other materials that require a high pressure of corrosive process gas, either consisting only of the element to be incorporated, or, as in the form of a precursor, of molecules containing other elements that are not intended to be incorporated in the film.

It is thus the object of the present invention to improve, at least in part, the described disadvantages of the coating apparatus or methods of coating a substrate. It is in particular the object of the present invention to provide a coating apparatus and a method of coating a substrate by which a high stoichiometric control with preferably a simultaneous largely free selection of a coating atmosphere, preferably with respect to both the process gas used and the pressure of the coating atmosphere, can be provided in a particularly simple and inexpensive manner.

The above object is satisfied by the claims of the present invention. This object is in particular satisfied by a coating apparatus for coating a substrate having the features of the independent claim 1. The object is further satisfied by a process chamber for a coating apparatus having the features of the independent claim 16. Furthermore, the object is satisfied by a method of coating a substrate having the features of the independent claim 17. Furthermore, the object is satisfied by a substrate coated with at least one material layer having the features of the independent claim 23. Further features and details of the invention result from the dependent claims, from the description, and from the drawings. In this respect, features, details and advantages of a coating apparatus in accordance with the invention also apply in connection with a process chamber in accordance with the invention, a method in accordance with the invention, and a coated substrate in accordance with the invention, and vice versa in each case, so that reference is or can always be mutually made with respect to the individual aspects of the invention.

In accordance with a first aspect of the invention, the object is satisfied by a coating apparatus for coating a substrate of a substrate material with at least one material layer of a layer material, said coating apparatus comprising a process chamber having a process volume for receiving a substrate holder for arranging the substrate, wherein the substrate holder is arranged in a fixed position in the process volume such that the substrate holder can furthermore be provided rotatable and/or movable essentially in a plane normal to the deposition direction as a whole, wherein the process chamber has a chamber wall for at least substantially completely enclosing the process volume; a gas system connected in a fluid-communicating manner to the process volume for generating a coating atmosphere in the process volume; and a source holder arranged in the process volume and providing at least one source material, wherein each of the at least one source materials is provided as a pure chemical element, said coating apparatus further comprising a source heating laser. A coating apparatus in accordance with the invention is characterized in that the source heating laser is configured to provide a continuous or at least substantially continuous separate beam of laser light for each of the at least one elemental source materials and the process chamber has a coupling-in apparatus having at least one coupling-in section in the chamber wall for conducting the separate beams of laser light of the source heating laser into the process volume for thermally evaporating and/or sublimating below a plasma generation threshold of the source material by the laser light, wherein the source holder and the substrate holder are further arranged relative to one another such that thermally evaporated and/or sublimated source material originating from the at least one source material can be deposited on the substrate for an at least partial formation of the layer material of the material layer.

The above described method for depositing material layer on a substrate using source material thermally evaporated and/or sublimated below the plasma threshold of the respective source material by a continuous or essentially continuous laser beam can be denoted as thermal laser epitaxy (TLE).

It must be pointed out that the substrate holder can be configured to hold a plurality of substrates and/or that the coating apparatus can be configured to hold a plurality of substrate holders having one or more substrates. In this respect, the coating apparatus can be used for the simultaneous coating of a plurality of substrates.

A substrate of a substrate material can be vapor-coated or coated with at least one material layer of a layer material by a coating apparatus in accordance with the invention. A coating apparatus in accordance with the invention has a process chamber in which the coating of the substrate can be performed. An interior of the process chamber is substantially formed by a process volume that in turn is at least substantially completely enclosed by a chamber wall. At least substantially enclosed in the sense of the invention in particular means that the chamber wall preferably only has openings and/or feedthroughs that are in turn completely closable.

As widely used in MBE, the chamber wall can be of multilayer design and can e.g. include a gas-cooled or liquid-cooled jacket to achieve the lowest possible residual impurities in the process volume. Particularly low pressures of the coating atmosphere can also be achieved in this way. Technical coolants such as water, alcohols, liquid nitrogen, or liquid helium can be used as coolants.

A closed process volume, in particular for providing a preferably controllable and/or adjustable coating atmosphere, can be provided in this way. The coating atmosphere itself is generated by a gas system of the coating apparatus in accordance with the invention, said gas system being connected in a fluid-communicating manner to the process volume.

A coating atmosphere in the sense of the invention is in particular characterized by the parameters of the used process gas for the coating atmosphere and its pressure. A mean free path length of the source materials evaporated and/or sublimated in the course of the coating of the substrate can, for example, be set by the pressure of the coating atmosphere.

Furthermore, the process gas used can likewise be selected in accordance with the material layer to be produced or its layer material. For example, a process gas that includes molecular oxygen and/or ozone can be used to produce oxides, whereby the oxidation processes necessary for the formation of the oxides can be made possible. Accordingly, the process gas can provide the element nitrogen required for the formation of nitrides, for instance as molecular nitrogen or ammonia. Accordingly, the process gas can provide the element carbon required for the formation of carbides, for instance as molecular methane or butane.

The substrate to be coated is arranged in the process volume itself, in particular received and held by a substrate holder. The substrate holder is overall arranged in a fixed position in the process volume. In the sense of the invention, such a fixed-position arrangement in particular comprises that the substrate holder can furthermore be provided rotatable as a whole and/or, if present, individual substrates can also be provided rotatable on the substrate holder, whereby a further improvement of a homogeneity of the material layer produced on the respective substrate can be provided. It also comprises that the substrate holder can be moved linearly, preferably in the horizontal direction, or along an arbitrary path in the horizontal plane, to improve the homogeneity. Both rotation and movement may be combined.

A source holder is arranged relative to the substrate holder and in turn has at least one source material. In turn, the source material can preferably be present as a freestanding solid cylinder or received in a source crucible. A particularly large selection possibility of usable source materials can thereby be provided. The source holder and the substrate holder can preferably be arranged in parallel with and/or directly opposite one another, whereby the source surface of the source material and the substrate surface can likewise be arranged directly opposite one another and/or can preferably be arranged in parallel with one another.

Essential for the present invention, each of the at least one source materials is provided as a pure chemical element. If a layer material comprising only a single chemical element as constituent is aimed at, an extremely high purity of the deposited layer material can be achieved, preferably further supported by using a high vacuum (pressure 10⁻³-10⁻⁸ hPa) or even ultrahigh vacuum (pressure 10⁻⁸-10⁻¹¹ hPa) as coating atmosphere.

In the sense of the invention, in particular as an alternative or in addition to a reception of the source material in a source crucible, a source element can be used in which the source material itself can be used to arrange and/or fasten the source material in the source holder. Thus, the source material can, for example, be bar-shaped and/or rod-shaped, wherein a first end of said bar is heated and is thereby thermally evaporated and/or sublimated and the bar is arranged and/or fixed at its lateral surface and/or its opposite second end in the source holder. This can in particular be implemented with source materials having a poor thermal conductivity since the first end of the bar can be sublimated and even melted on or liquefied in this respect, wherein the remaining bar simultaneously remains cold and solid. Particularly long uptimes, that is times without necessary source changes, can be provided in this way. In particular, this arrangement avoids the use of crucibles and therefore the contamination of the source material by the crucible material. The very local heating in this arrangement also leads to high purity due to the absent or strongly reduced parasitic heating of parts nearby to the source, e.g. its holder, which could release impurities due to this heating and thereby contaminate the deposited layer.

A particularly good and in particular uniform coating of the substrate with the thermally evaporated and/or sublimated source material can thereby be provided. Possible spacings between the source holder and the substrate holder are, for example, 20 to 200 mm, preferably 60 mm. Shutter covers can also be arranged between the source holder or the individual source materials and/or source crucibles and the substrate in order to shadow evaporated and/or sublimated source material of a source or of a source crucible in a targeted and in particular controlled and/or regulated manner with respect to the substrate. However, as the evaporation and/or sublimation is highly linked to the presence of the respective laser beam impinging on the surface of the source material, already switching on and off said laser beam can be effective for controlling and/or regulating the evaporation and/or sublimation of individual source materials. The low thermal mass of small sources and at the same time the high power and short turn-on and turn-off times of the lasers in the method and apparatus according to the present invention are favorable for this mode of operation. In particular, this enables the desired high stoichiometric control on the production of the layer material of the material layer.

Provision can particularly preferably further be made that the source holder and the substrate holder are formed at least substantially identically. At least substantially identically can in particular comprise a size expansion of the source holder and of the substrate holder. In this way, provision can also be made that a replaceability of the substrate holder, such as is generally known with MBE, can also be applied to the source holder. Thus, a replacement and/or refill source can, for example, be provided with its own source holder in a separate holding volume that is only separated by a slide valve from the process volume.

An atmosphere in the holding volume can be set or become set independently of the process volume, wherein preferably the holding volume is likewise filled with the coating atmosphere. A replacement of the sources or of the source holder can be performed in this manner without a complete fracturing and re-establishment of the coating atmosphere being necessary.

In the coating apparatus in accordance with the invention, provision is made in a manner essential to the invention that a laser light of a source heating laser is used for a heating and thermal evaporation and/or sublimation of the source material. For this purpose, the coating apparatus in accordance with the invention has a source heating laser. The source heating laser as part of the coating apparatus itself can be set up directly close to the process chamber or can even be arranged directly at it, wherein the source heating laser can furthermore preferably also be set up remote from the process chamber and only the necessary laser light of the source heating laser can be conducted to the process chamber. The process chamber of the coating apparatus in accordance with the invention in particular has a coupling-in apparatus having at least one coupling-in section to enable a conducting of the laser light of the source heating laser into the process volume. For this purpose, the coupling-in section is arranged in the chamber wall of the process chamber. The coupling-in section can, for example, have a coupling-in window, preferably composed of quartz glass. A feedthrough, for example of optical fibers, as a coupling-in section is also conceivable.

In accordance with the invention, the source heating laser is configured to provide laser light continuously or at least substantially continuously. For example, a continuous or at least substantially continuous provision in the sense of the invention can, for example, comprise an uninterrupted emission of laser light over time intervals of a few microseconds or longer, preferably milliseconds or longer. This enables the source heating laser to be operated such that the laser light is continuously or at least substantially continuously incident on the source material. The source heating laser is thus particularly preferably not operated in a pulsed manner, that is with high laser energies and/or lengths of the laser pulses in the nanosecond range. A particularly constant and controllable or adjustable energy input of the laser light into the source material can be provided in this way. A constant and/or controllable and adjustable temperature of the source material and thus a resulting evaporation rate and/or sublimation rate can be made possible in this way. In the sense of the invention, a continuous or at least substantially continuous provision is in particular also present when the provision of laser light indeed comprises a repeated sequence of emission phases and pause phases, but a ratio of the temporal lengths of these phases is set such that the constant temperature of the source material indicated above is adopted. In this respect, in the sense of the invention, a temperature of the source material is considered to be constant if it fluctuates by less than 30%, preferably by less than 10%, in a time period that comprises a plurality of emission phases and pause phases.

Furthermore, an energy of the laser light of the source heating laser is set such that a plasma generation threshold of the source material is not reached by the laser light. In other words, no plasma is generated on the incidence of the laser light on the source material since the energy provided by the laser light and acting on the source material is not sufficient therefor. A purely thermal evaporation and/or sublimation of the source material, which takes place below the plasma generation threshold of the source material, can thereby be ensured. For different source materials having a respective material-specific plasma generation threshold, the correspondingly formed laser light or a correspondingly designed source heating laser can in particular also be used in a coating apparatus in accordance with the invention.

Due to the heating and in particular thermal evaporation and/or sublimation of the source material by the laser light, no or at least substantially no electrical components are required in the process volume of the process chamber. Restrictions with respect to a type and a pressure of the process gas used can thus be avoided in a coating apparatus in accordance with the invention. The used pressure of the coating atmosphere is thus substantially only limited by the free path length of the thermally evaporated and/or sublimated material particles of the source material or can be suitably set for a desired or required free path length in order to ensure a reaching of the substrate by the source material. With a spacing between the substrate and the source holder of 60 mm, this leads to a still realizable pressure of the coating atmosphere of approximately 10⁻¹ mbar.

As described above, the source material is provided arranged in a source holder. A plurality of source materials, preferably different source materials, are also possible.

Essential for the present invention, each of the at least one source materials is provided as a pure chemical element, and for each of said source materials a continuous or at least essentially continuous separate beam of laser light is provided by the source heating laser.

Thereby, if a layer material comprising only a single chemical element as constituent is aimed at, an extremely high purity of the deposited layer material can be achieved, preferably further supported by using a high vacuum (pressure 10⁻³-10⁻⁸ hPa) or even ultrahigh vacuum (pressure 10⁻⁸-10⁻¹¹ hPa) as coating atmosphere.

Alternatively, if a layer material comprising two or more chemical elements as constituents, namely a compound, is aimed at, each of the chemical elements needed for said layer material are provided separately, either as a separate source material or by the coating atmosphere. In this case, an extremely high purity of the deposited layer material can also be achieved due to the pureness of the initial materials.

Additionally, if two or more preferably different source materials, each of them provided as pure chemical element, are positioned by the source holder within the reaction volume, each of these source materials can be switched in or switched out during an ongoing coating process. Preferably, said switching in and/or out is provided by switching on and/or off, respectively, of the respective laser beam used for thermally evaporating and/or sublimating said source material. Alternatively, or additionally, also shutter covers constructed as already described above can be used.

A high control of a stoichiometry of the material layer produced or of the layer material can be provided in this way. At the same time, and as already mentioned above, the high source purity provided by the pure chemical elements used as source materials, is transferred to the purity of the layer material of the produced material layer on the substrate. A high source purity can, for example, be provided by already very pure source materials, in particular by using source crucibles to receive these source materials. The shutter covers are preferably in particular arranged such that the irradiation of the laser light onto the corresponding source crucible and/or the corresponding source material is not blocked or is at least substantially not blocked by the shutter cover, in particular in none of the positions of the shutter cover.

In summary, in a coating apparatus in accordance with the invention, a high stoichiometric control can thus be provided with a simultaneously free or at least little restricted selection of the parameters of the coating atmosphere. Overall, oxides can, for example, thereby be particularly easily produced as the coating material and with a high purity on a simultaneous good control of the stoichiometry, wherein a doping, in particular a modulated doping, of these oxides can in particular also be made possible by a coating apparatus in accordance with the invention.

The coating apparatus according to the present invention can be characterized in that the layer material is a compound comprising two or more chemical elements, wherein at least one of the two or more chemical elements originates from one of the at least one source materials. As already mentioned above, the purity of the used at least one source material provided as pure chemical element results in a likewise high purity of the formed compound.

Additionally, the coating apparatus according to the present invention can comprise that the coating atmosphere comprises a reaction gas, wherein at least one of the two or more chemical elements of the layer material originates from the reaction gas. As likewise already mentioned above, at least one of the constituents forming the compound aimed at as layer material can be provided by the reaction gas used for forming the coating atmosphere. For instance, by using a reaction gas providing oxygen atoms, such as for instance molecular oxygen or ozone, an oxide of the chemical element provided as evaporated and/or sublimated source material can be deposited onto the substrate. In another example, the provision of a reaction gas providing nitrogen, such as for instance molecular nitrogen or ammonia, renders possible the deposition of a nitride formed as compound from the evaporated and/or sublimated source material and nitrogen atoms provided by the reaction gas.

Further, the coating apparatus according to the present invention can comprise that a surface of the substrate is prepared such that the compound is formed only on said surface of the substrate. As already mentioned above, the compound to be deposited onto the substrate as layer material is not provided as source substance, in contrast to for instance to the approach used in PLD. By preparing the surface of the substrate, for instance by respectively altering its chemical and/or physical properties, or by heating it to a specific temperature during the process, the formation of the compound on the surface of the substrate can be supported or even rendered possible in the first place. Also, this measure helps increasing the purity of the deposited compound, and hence of the layer material.

Further, the coating apparatus according to the present invention can be enhanced by that the apparatus comprises a substrate heating laser for heating the substrate, wherein the substrate heating laser is constructed for heating the substrate such that at least one chemical element of the compound forming the layer material desorbs from the substrate if not incorporated into the compound forming the layer material. In other words, the at least one chemical element provided as evaporated and/or sublimated source material cannot deposit onto the surface of the substrate, as long as it is not accompanied by the remaining chemical elements needed for forming the compound aimed at as layer material. This is especially of advantage if the layer material has a higher desorption temperature than said source material. In this case, this approach allows an adsorption-controlled way of depositing the layer material onto the surface of the substrate. The evaporated and/or sublimated at least one source material is provided in abundance, and the further needed materials are provided such that the compound is formed on the surface of the substrate, especially with the intended stoichiometry. An especially versatile control of the deposition process can thereby be provided. In addition, an extremely high purity and structural perfection of the deposited layer can therefore be provided.

The coating apparatus according to the present invention can also be characterized in that the process chamber comprises a monolithic chamber body providing the whole chamber wall. In other words, the chamber body encloses the whole reaction volume, whereby the chamber body is made of a single piece. in most of the cases a single piece of metal. Seams along contact lines originating from connecting different parts of a multisegmental process chamber, which may cause leaks and/or outgassing, can thereby be avoided.

In an enhanced embodiment, the coating according to the present invention can comprise that the chamber body consists of aluminum or of an aluminum alloy. Aluminum and aluminum alloys comprise the properties that they are lightweight, in particular compared to stainless steel, which is a common material for constructing process chambers for coating apparatuses. Further, aluminum and aluminum alloys comprise, also in particular compared to stainless steel, a high thermal conductivity. This is especially of advantage for the intended usage of the process chamber with continuous or essentially continuous laser beams as implemented for TLE as described herein, as, in particular compared to pulsed laser deposition (PLD), the overall energy deposit caused by laser light can be much higher, Hence, by using aluminum or aluminum alloy as material for the chamber body, energy deposited into the chamber body can be effectively spread over a large volume, and harm to the integrity of the chamber body can be avoided.

In addition, the coating apparatus according to the present invention can be further enhanced by that the process chamber comprises cooling means for a fluid cooling of the process volume. Preferably, the fluid cooling is based on a respective coolant flowing in cooling ducts. Cooling the process chamber provides the advantage that the process volume can actively be kept at a certain temperature. Energy deposited into the process volume, in particular by the one or more laser beams used for evaporating and/or sublimating source material, can thereby be compensated. Also, energy deposited into the chamber wall by intentionally and in particular unintentionally impinging of said one or more laser beams can be transferred into a coolant of the fluid cooling and thereby carried away.

It is to be noted by accordingly heating the coolant, also a rise in temperature of the process volume can be achieved.

According to another enhanced embodiment of the coating apparatus according to the present invention, the cooling means comprise coolant ducts, wherein further the coolant ducts are at least partly integrated in the chamber body. Thereby, a thermal connection between the fluid cooling, in particular the coolant flowing in the coolant ducts, and the chamber wall, which is completely formed by the chamber body, can be maximized.

Further, the coating apparatus according to the present invention can be characterized in that the process chamber comprises an airtight sealable lock with a lock volume, wherein the lock comprises a first lock door sealable against the process volume and a second lock door sealable against the environment, the process chamber further comprising an exchange mechanism for exchanging the at least one source material, wherein the exchange mechanism is constructed to operate within the process volume and to grab and move the at least one source material between the source holder and the lock volume. In other words, said sealable lock comprises two lock doors, both of them allowing access to the lock volume. The first lock door opens towards the process volume, the second lock door opens towards the environment. As described in the following, this setup allows exchanging source materials without the need of breaking or contaminating the coating atmosphere.

For removing one of the at least one source materials, first of all both lock doors are closed and sealed, and the atmosphere within the lock volume is equalized to the coating atmosphere in the process volume by the gas system of the coating apparatus. After that, the first lock door is opened, and subsequently the exchange mechanism is used for grabbing the respective source material and moving it into the lock volume. Next, the exchange mechanism retreats into the process volume, the first lock door closes, and the atmosphere in the lock volume is equalized to the atmosphere of the environment. After that, the second lock door opens and the respective source material can be removed from the lock volume.

The process of adding a new source material to the process volume is carried out in reverse order. First, both lock doors are closed and sealed, and the atmosphere within the lock volume is equalized to the atmosphere of the environment. After that, the second lock door is opened, and the new source material is put into the lock volume. After locking the second lock door, the atmosphere within the lock volume is equalized to the coating atmosphere within the process volume. This allows opening the first lock door next, again without breaking the coating atmosphere. The exchange mechanism is then used for grabbing the respective source material and moving it from the lock volume to the source holder.

Optionally, as final step the first lock door can close, for providing the advantage of a minimized total volume of the process volume.

According to a further enhanced embodiment, the coating apparatus according to the present invention can comprise that the exchange mechanism is arranged within the lock volume. Thereby, the first lock door can stay sealed when accessing the exchange mechanism. In other words, the exchange mechanism can be reached, for instance for maintenance work or the replacement of components, without the need for breaking the reaction atmosphere.

In addition, the coating apparatus can also be characterized in that the lock comprises a divider for dividing the lock volume a first compartment and a second compartment sealable to each other by the divider, wherein the first compartment extends between the divider and the first lock door, and the second compartment extends between the divider and the second lock door. In other words, the first compartment is arranged between the second compartment and the process volume, and sealable against both of them. Likewise, the second compartment is arranged between the first compartment and the environment, and again sealable against both of them. Preferably, both compartments are connected to the coating system's gas supply separately. The risk of contamination of the process volume by the atmosphere of the environment can thereby be lowered further. In addition, the first compartment can be used for storing source materials and/or substrates. In particular, also the exchange mechanism can be arranged within the first compartment.

Further, the coating apparatus according to the present invention can be enhanced in that the lock comprises a source holding structure arranged in the lock volume, wherein the source holding structure is constructed to receive the at least one source material placed in the lock volume by the exchange mechanism. Said source holding structure can for instance be constructed similar to the source holder present in the process volume. By providing a source holding structure, the spatial position of the source material to be exchanged within the lock volume can be specified and fixed. This provides the advantage that a construction and/or a training of the exchange mechanism can be simplified, as random arrangements of the source material within the lock volume can be neglected. Further, contaminations of the source material by unintentional contact to the walls enclosing the lock volume can be avoided. If the lock volume is divided into compartments by the divider, the source holding structure preferably is arranged in the first compartment.

Also, the coating apparatus according to the present invention can comprise that the exchange mechanism is constructed to grab and move all source materials simultaneously. In other words, in this embodiment, all source materials present in the process volume are exchanged together. A time and cost consuming successive exchange of several source materials can thereby be avoided.

It is to be noted that also an exchange of some, especially not all, source materials at the same time can be provided, for instance by providing structurally connected subsets of two or more source materials.

In addition, the coating apparatus can also comprise that the exchange mechanism is constructed to also grab and move the substrate between the substrate holder and the lock volume. Thereby, not only one or more source materials but also the substrate can be exchanged easily. Especially, only one sealable lock has to be provided for both tasks. The structural setup of the process chamber can thereby be simplified.

It is to be noted that all advantages described above with respect to the exchange of source materials by the exchange mechanism through the sealable lock can also be provided for the substrate, if the exchange mechanism is accordingly constructed. Especially, putting uncoated substrates into the process volume and extracted substrates coated with the intended layer material from the process volume can be provided without breaking the coating atmosphere.

The coating apparatus according to the present invention can also be enhanced in that the lock comprises a substrate holding structure arranged in the lock volume, wherein the substrate holding structure is constructed to receive the substrate placed in the lock volume by the exchange mechanism. Analogous to the source holding structure described above, also said substrate holding structure can for instance be constructed similar to the substrate holder present in the process volume. By providing a substrate holding structure, the spatial position of the substrate to be exchanged within the lock volume can be specified and fixed. This provides the advantage that a construction and/or a training of the exchange mechanism can be simplified, as random arrangements of the substrate within the lock volume can be neglected. Further, contaminations of the substrate by unintentional contact to the walls enclosing the lock volume, especially after the coating process, can be avoided. If the lock volume is divided into compartments by the divider, the substrate holding structure preferably is arranged in the first compartment.

In a coating apparatus in accordance with the invention, provision can particularly preferably be made that the source material can be directly heated and thermally evaporated and/or sublimated by the laser light by a direct irradiation of the laser light onto a source surface of the source material. In other words, the laser light of the source heating laser is conducted into the process volume of the coating apparatus such that it is incident on a source surface of the source material.

A direct energy transfer from the laser light to the source material, without, for example, the detour via an intermediate heating of further elements, in particular, for example, of a source crucible, can be provided in this way. The source surface of the source material thus at least substantially becomes a location in the total process volume with the highest temperature, whereby a consistently high purity of the source material can be provided. This is due to the fact that process gas and/or evaporated or sublimated material in the process volume is preferably deposited at colder locations, whereby particularly a hot source surface does not have to suffer any or only insignificant contamination.

Furthermore, in a coating apparatus in accordance with the invention, provision can be made that the light beam encloses an angle of incidence between 0° and 90°, in particular between 30° and 70°, preferably 50°, with a surface normal to a crucible surface of the source crucible having source material and/or with a surface normal to a source surface of the source material. At an angle of incidence of 0°, this means a perpendicular incidence of the laser light on the crucible surface and/or the source surface, a particularly high energy density can be provided at the point of irradiation or on the total irradiation surface.

A particularly good energy transfer between the laser light and the source material is the result. At the same time, the advantageous arrangement of the substrate directly opposite the source material as described above cannot take place in this case, however. Furthermore, a back reflection of the laser light that is possible at an angle of incidence of 0° can also cause instabilities of the laser source and a stronger coating of the entrance window.

A particularly large angle of incidence leads to a flat incidence, at 90° even to a grazing incidence, of the laser light on the source surface, whereby the energy of the laser light is distributed over a larger area of the source material and thus the energy transfer per unit area decreases. An angle of incidence between 30° and 70°, preferably an angle of incidence of 50°, represents good compromises of the initially described extreme values at which a good transfer of the energy of the laser light to the source material and simultaneously a preferred relative arrangement of the source holder and the substrate holder can be provided. Research results on laser welding furthermore suggest that angles of incidence between 30° and 70° also lead to an improved absorption of the laser light by metallic surfaces.

A coating apparatus in accordance with the invention can also be configured in that an intensity and/or a wavelength of the laser light is/are adapted to the corresponding source material, with preferably the laser light having an intensity of 0.01 W to 50 kW and/or a wavelength of 10⁻⁸ m to 10⁻⁵ m. An adapted design of the intensity and/or the wavelength of the laser light to the source material can, for example, be performed by taking into account the vapor pressure and/or the absorption behavior of the source material. Thus, a source material with a higher vapor pressure will require a lower laser light power or intensity than a source material with a lower vapor pressure. Source materials that have a high absorption capability can also be heated and thermally evaporated and/or sublimated by a lower intensity of laser light than source materials in which, for example, a high reflectivity reduces an absorption capability of the source material.

The absorption behavior of the source material can in particular also have a dependence of an irradiated wavelength, wherein this can in turn be taken into account by a corresponding selection of a wavelength of the laser light of the source heating laser. Overall, in this preferred embodiment of a coating apparatus in accordance with the invention, a suitable source heating laser can thus be selected adapted to the source material in order to be able to provide a particularly good heating and thermal evaporation and/or sublimation of the source material.

Furthermore, in a coating apparatus in accordance with the invention, provision can be made that the process chamber has, at an inner side of the chamber wall, at least one beam catcher for at least partly absorbing reflected laser light, in particular laser light reflected at the crucible surface of the source crucible and/or at the surface of the source material, with the beam catcher being arranged in a spatial plane, which the light beam and the surface normal to the crucible surface of the source crucible and/or to the source surface of the source material span, and at a section of the chamber wall that is an oppositely disposed section in accordance with the angle of incidence of the coupling-in section.

It can occur on an irradiation of the laser light onto the source crucible or the source material that the laser light is reflected at the crucible surface and/or at the source surface. This reflection usually takes place at least substantially in accordance with the law of reflection. In this embodiment of a coating apparatus in accordance with the invention, provision is therefore made to arrange a beam catcher in the spatial plane, which is spanned by the surface normal to the crucible surface or to the source surface and to the angle of incidence of the laser light, at the chamber wall in a spatial region in accordance with the angle of incidence of the coupling-in section. Due to this beam catcher, it can in particular be prevented that reflected laser light incident directly on the chamber wall causes a heating of the chamber wall.

In other words, a generation of a further heat source by a heating of the chamber wall can be prevented by the beam catcher. The beam catcher can particularly preferably also be actively cooled for this purpose. Contaminants in the coating atmosphere due to a degassing and/or an evaporation of a point of the chamber wall heated or heated up by reflected laser light can be reduced or even completely prevented in this way. A purity of the generated material layer on the substrate can be further increased in this way.

Furthermore, in a coating apparatus in accordance with the invention, provision can be made that the source holder has two or more, in particular three, preferably six, source materials, each preferably present as a freestanding solid cylinder or received in a source crucible, with the source material being able to be heated and thermally evaporated and/or sublimated by a separate light beam of laser light, and with the source materials preferably being different. In this way, provision can in particular be made that a plurality of source materials, preferably different source materials, can be provided with a single source holder. More than six source materials, for example twelve source materials, are also conceivable here. A sequential implementation and production of material layers having different layer materials can thereby be made possible, on the one hand. On a simultaneous heating and thermal evaporation and/or sublimation of different source materials, preferably provided in individual source crucibles, layer materials can also be produced with the most varied compositions, for example controlled and/or regulated by laser beam intensity variations or the shutter covers already described above. Provision is in particular made that each individual source material or each individual source crucible can be heated and thermally evaporated and/or sublimated by a separate laser light beam. The separate light beams can come either from different source heating lasers or from a single source heating laser whose light beam is, for example, split by beam splitters and supplied to the individual source materials. Provision can in this respect preferably be made that the individual separate light beams for the individual source crucibles or source materials at least have different intensities that can preferably be regulated and controlled by corresponding setting elements. Light beams having different wavelengths, for example to increase the absorption of the laser light by the individual source materials, can also be provided.

In accordance with a further development of a coating apparatus in accordance with the invention, provision can be made that the coupling-in apparatus has a common coupling-in section for conducting at least two of the separate light beams into the process volume. In this way, it can, for example, be made possible that the two separate light beams are introduced into the process volume by a common vacuum flange. A design of the process chamber, in particular of the chamber wall for enclosing the process volume, can be simplified in this way. Provision can in this respect in particular be made that the two separate light beams are conducted into the process volume via a common coupling-in window. Alternatively, provision can also be made that separate coupling-in windows for the separate light beams are provided at the coupling-in section.

Alternatively or additionally, a coating apparatus in accordance with the invention can be further developed in that the coupling-in apparatus has at least two separate coupling-in sections for conducting a respective at least one of the separate light beams into the process volume, with in particular the spatial planes, which the respective light beam, which is conducted into the process volume by one of the separate coupling-in sections, and the surface normal to the crucible surface of the corresponding source crucible and/or to the source surface of the corresponding source material span, enclosing an angle of less than 180°, preferably between 90° and 150°, particularly preferably of 120°.

Alternatively or additionally in the sense of the invention in particular means that, on a provision of more than two separate light beams, a plurality of these light beams can also share a common coupling-in section, overall all the light beams can be conducted into the process volume by at least two coupling-in sections. An even greater design freedom in the planning and design of a coating apparatus in accordance with the invention can thereby be provided.

Thus, in a preferred embodiment of a coating apparatus in accordance with the invention, provision can, for example, be made in the case of a source holder having six source crucibles or source materials that a respective three of these source materials are arranged as triples on the source holder at a spacing of 120° from one another. Each source material of these source material triples is heated and thermally evaporated and/or sublimated by a separate light beam, wherein the light beams for a source material triple are each preferably conducted into the process volume in a common coupling-in section.

In other words, a triple bundle of light beams that come from a common coupling-in section is provided for each of the source material triples, wherein the two thus present coupling-in sections are arranged spaced apart from one another in the chamber wall of the process chamber. Due to an angular arrangement of these coupling-in sections with respect to one another such that the spatial planes spanned by the individual light beams and the surface normals of the respective source surfaces are arranged at an angle of less than 180°, preferably 120°, from one another, a reflection of light beams of one of the coupling-in sections to the other coupling-in section can in particular be prevented from taking place. In this way, an arrangement of a corresponding beam catcher for correspondingly reflected light beams at the corresponding location of the chamber wall can in particular also be made possible.

A coating apparatus in accordance with the invention can also be configured in that at least one of the light beams, preferably all of the light beams, has a focal area, with, in the focal area, the light beam having a minimum extent perpendicular to a light direction of the light beam, with the focal area further being arranged in the process volume between the coupling-in section and the corresponding source material or the corresponding source crucible. Such a focusing of the light beam in a focal region generally enables as large as possible an extent of the light beam at the coupling-in section, in particular at a coupling-in window of the coupling-in section. A low load on the coupling-in section on the conducting through of the laser light of the source heating laser can be provided in this way, wherein the focal area can simultaneously be selected such that a good heating and thermal evaporation and/or sublimation of the source material can be ensured, in particular by an ideal illumination of a source surface of the source material.

It can further be provided by an arrangement of the focal area between the coupling-in section and the source material or the source crucible that the light beam is more and more extended after the source material or the source crucible as the spacing from the source material or the source crucible increases. In other words, the energy density of the light beam becomes smaller and smaller as the spacing behind the source material or the source crucible increases. Damage, in particular unintentional damage, to the chamber wall, as can occur in a focal area, viewed from the coupling-in section, behind the source material or the source crucible if they are absent, can be reliably avoided in this way.

Furthermore, a coating apparatus in accordance with the invention can be further developed in that the focal areas of at least two of the light beams overlap, in particular completely or at least substantially completely overlap, with preferably the coupling-in apparatus having a common coupling-in section for conducting these at least two light beams into the process volume. The focal area of the light beam is in particular that area in which the energy density, that is the light energy per unit area, of the light beam is at a maximum. This energy density can in particular be so high that there is a risk of damage to material and/or elements of the coating apparatus.

Due to a coincidence or overlapping of the focal areas of at least two of the light beams, they are in other words confocal. It can thereby in particular be provided that a number of these locations with a high energy density of the light beams are minimized. A reduction of the danger for material of the coating apparatus can be provided in this way. A spatial proximity of the two light beams, which is necessary for such a coincidence of the focal areas for two separate light beams, can be particularly easily provided by a conducting of the two light beams by the same coupling-in section into the process volume.

A coating apparatus in accordance with the invention can particularly preferably be further developed in that the process chamber has at least one heating laser aperture having an aperture opening, with the heating laser aperture being arranged in the process volume such that the focal area of at least one of the light beams coincides or at least substantially coincides with the aperture opening. Such a heating laser aperture can preferably be formed from a light-tight and/or material-tight aperture material.

Due to the arrangement of the heating laser aperture with its aperture opening at the focal area of the at least one light beam, the heating laser aperture itself is likewise arranged between the coupling-in section and the source holder or the source material and a corresponding source crucible. Provision can preferably be made that the heating laser aperture is formed or arranged at least substantially perpendicular to the light direction of the light beam.

Due to an arrangement of the heating laser aperture such that the focal area of at least one of the light beams coincides or at least substantially coincides with the aperture opening of the heating laser aperture, it can be ensured that no or at least substantially no influence by the heating laser aperture on the light beam takes place. Provision can simultaneously be made that source material that has been evaporated and/or sublimated by the light beam of the source heating laser and that propagates in the direction of the coupling-in section is collected by the heating laser aperture. Since the heating laser aperture is arranged between the source holder and the coupling-in section, the evaporated or sublimated source material is deposited or at least substantially deposited on the heating laser aperture.

Provision can therefore preferably be made that the heating laser aperture completely or at least substantially completely covers the coupling-in section, viewed from the source holder. A prevention or at least a considerable reduction of the deposition of source material on the coupling-in section, in particular on a coupling-in window of the coupling-in section, can be provided in this way. An extension of the service life, a reduction of a proneness to maintenance, or an extension of maintenance cycles with respect to the coupling-in section can be provided in this way.

A coating apparatus in accordance with the invention can particularly preferably be further developed in that the aperture opening is formed in the heating laser aperture by the laser light of the source heating laser. In other words, the aperture opening is burned into the heating laser aperture or the material of the heating laser aperture is locally melted on by the laser light of the source heating laser in order to create the aperture opening. This brings about two major advantages. For example, on the one hand, the local arrangement of the aperture opening in the heating laser aperture can be particularly easily adapted to the location of the focal area of the light beam in this way. An ideal size of the aperture opening, adapted to the focal area of the light beam, can also be particularly easily provided in this way.

Furthermore, provision can be made in a coating apparatus in accordance with the invention that the process chamber has at least one thermocouple for determining a temperature of the at least one source material and/or of the corresponding source crucible, with in particular the at least one thermocouple and/or the source holder having a movable fastening section for moving the thermocouple between a measurement position, in which it contacts the source material and/or the corresponding source crucible, and a release position, in which it is arranged remote from the source holder for a movement thereof, and/or for moving the source holder to reversibly provide an end position of the source holder in which the at least one thermocouple contacts the source material and/or the corresponding source crucible in its measurement position.

A measurement of a temperature of the source material or of the source crucible, and thus at least indirectly of the source material, can in particular be provided by such a thermocouple. This measured temperature value can in particular, for example, also be used for a control and/or regulation of the source heating laser, preferably with respect to an intensity of the source heating laser. Consistent coating conditions in a coating apparatus in accordance with the invention, in particular with respect to a provision of evaporated and/or sublimated source material, can be particularly easily provided in this way.

The at least one thermocouple is preferably movably arranged in the process chamber, for example provided via a fastening section. Thus, the thermocouples can, for example, resiliently contact the respective source materials or source crucibles. Due to a movement of the thermocouple between a measurement position, contacting the source material or the source crucible, and a release position, arranged remotely with respect to the source material or the source crucible, provision can in particular be made that the source holder itself can likewise be moved and without impediment by the thermocouples. The above described exchange of the source holder, analogously to the substrate holder, can in this way be made possible in a particularly simple manner, in particular without impediment by the thermocouples.

Alternatively or additionally, the source holder with arranged source materials, these in turn preferably received in source crucibles, can also be movably arranged in the process volume. In this way, on the transfer of the source holder, with a substantially fixed position, preferably the measurement position, of the thermocouples, the source holder can be moved into an end position by a lowering toward the thermocouple, wherein the thermocouple in particular resiliently contacts the source material and/or the source crucible in this end position of the source holder. In this embodiment, the replacement of the source holder described above can, analogously to the substrate holder, also be made possible in a particularly simple manner, in particular without impediment by the thermocouples.

A coating apparatus in accordance with the invention can also be configured in that the coupling-in apparatus has at least one further coupling-in section in the chamber wall for conducting laser light of a substrate heating laser into the process volume, with the laser light at least sectionally being present as a light beam in the process volume and the substrate material of the substrate being heatable by the laser light, in particular being directly heatable by direct irradiation, with preferably the laser light being adapted to the substrate material and/or having an intensity of 0.01 W to 50 kW and/or a wavelength of 10⁻⁶ m to 10⁻⁴ m.

A substrate heating, such as can be provided by the light beam of the substrate heating laser, makes it possible that the substrate itself forms one of the hottest locations in the process volume in addition to the source material. A generation of a coating of the substrate with a layer material of particular purity can be provided in this way. A heated substrate furthermore also enables a particularly uniform growth of the material layer since the evaporated layer material can extract kinetic energy from the heated substrate in order to distribute itself as uniformly as possible on the substrate surface. A laser having a longer wavelength than the source heating laser is preferably used as the substrate heating laser since the substrates that are usually used correspondingly have different absorption properties than the source materials. Thus, for a substrate that is a ceramic and/or itself an oxide, a longwave laser of, for example, a wavelength of 10.6 μm can be used, for example. The use of a CO₂ laser as a substrate heating laser has proven to be particularly advantageous with visibly transparent substrates.

Furthermore, in a coating apparatus in accordance with the invention, provision can be made that the gas system has a process gas supply for supplying a process gas into the process volume and a pump system for generating an underpressure in the process volume, with the pump system comprising a magnetically levitated turbopump. A provision of a specific process gas for the coating atmosphere in the process volume can in particular be made possible by such a process gas supply of the gas system.

In general and in principle, all gaseous substances can be used as the process gas. In the sense of the invention, any residual gas that remains in the process volume on a provision of low pressures in the range of 10⁻¹ mbar or lower is in particular also understood as process gas provided by the gas system.

A gas comprising molecular oxygen and/or ozone can be used as the process gas for the production of oxides, for example.

In contrast, a desired generation of nitrides as the layer material of the material layer can require a use of NH₃ or molecular nitrogen, in particular, for example, also ionized nitrogen.

Further process gases are, for example, also conceivable for a selenium-containing and/or sulfur-containing coating atmosphere.

A wide range of pressures of the coating atmosphere can in turn be provided by the pump system. A range of 10⁻¹⁰ mbar to 1 mbar can, for example, be generated as pressure by the pump system.

Known pump systems in accordance with the prior art in particular have a variable slide valve between the process volume of the process chamber and a lubrication-supported turbopump, wherein a setting of the suction power of the pump system and thus of the pressure in the process volume is in particular provided by an open state of the slide valve. This has the disadvantage that the total volume of the process volume is increased by the slide value, whereby a reaching of particularly low pressures, in particular in the lower range of the high vacuum or even ultra-high vacuum or lower, can be made more difficult.

In accordance with the invention, the pump system is therefore improved in that a magnetically levitated turbopump is provided that is preferably arranged in the pump system directly adjoining the process volume. This direct arrangement is in particular made possible in that no lubricants are required due to the magnetic support in this turbopump, whereby the turbopump can remain part of the process volume, without contaminating it by diffusing lubricant, on a switching off of turbopump, even in the case of a fault such as a power failure.

A suction opening of this magnetically levitated turbopump can be adapted and can be particularly large with respect to the process volume. The volume to be pumped can thereby be reduced overall, whereby a reaching of low pressure ranges can be simplified.

A slide valve, which is considerably smaller in accordance with the compression ratio of the magnetically levitated turbopump, can only be provided adjoining the magnetically levitated turbopump, said slide valve now, however, only being provided for a complete closure or release.

Since a magnetically levitated turbopump is restricted with respect to the reachable pressure level depending on the upstream pressure provided, a further, lubrication-supported turbopump is arranged adjoining the slide valve in order to generate a correspondingly low starting pressure for the magnetically levitated turbopump.

Further roughing pumps connected upstream of the second turbopump can also be provided for the operation, for example a scroll pump or a roots pump, preferably a diaphragm pump.

However, since this lubrication-supported turbopump is only used for roughing or backing pumping, it can be considerably smaller than the turbopump used in the prior art. Overall, pressures up to a range of 10⁻¹⁰ mbar and lower can be provided in this way.

In the case of a fault, the harmful diffusion of lubricant of the second turbopump into the process volume can be prevented by the slide valve described above. The two turbopumps are thus connected behind one another and preferably run continuously.

As long as no coating process takes place, at least the large magnetically levitated turbopump runs at full rotational speed and the slide valve between the pumps is open. In this respect, it is even possible to operate the small lubrication-supported turbopump continuously at 20% of the nominal rotational speed without the total end pressure that can be provided in the process volume being compromised.

During the coating process, the pressure regulation for the coating atmosphere can now not be achieved by the variation of a valve that is located before the large turbopump and that has a variable opening, but rather by a rotational speed variation of the large turbopump.

In commercial turbopumps, this rotational speed can be set precisely (+/−0.01%) in the range from 20% to 100% and allows a fine regulation of the pumping capacity in the range corresponding to about a factor of 10 in the pressure that can be provided.

For a setting of a specific process pressure of a process gas as the coating atmosphere, the pressure can therefore be predefined in the range of a factor 2 by the inflow of process gas, which is, for example, controlled by a mass flow regulator, and can then be finely readjusted by means of the rotational speed regulation of the magnetically levitated turbopump.

Due to the frequency specification with which it works, this rotational speed regulation can be provided much more precisely and reproducibly by today's microprocessor electronics than a mechanical regulation via the slide valve in accordance with the prior art. In other words, a control of the pressure level of the coating atmosphere in the interior of the process volume preferably no longer takes place via the position of the slide valve, but rather via the rotational frequency of the magnetically levitated turbopump, taking into account the supply rate of process gas by the process gas supply. This enables an even more precise and in particular more easily adjustable pressure level in the process volume in comparison with the prior art.

The invention thus also relates to a coating apparatus for coating a substrate of a substrate material with at least one material layer of a layer material, said coating apparatus comprising a process chamber having a process volume for receiving a substrate holder for arranging the substrate in a fixed position in the process volume, wherein the process chamber has a chamber wall for at least substantially completely enclosing the process volume; and a gas system connected in a fluid-communicating manner to the process volume for generating a coating atmosphere in the process volume, said coating apparatus further comprising a pump system for generating an underpressure in the process volume, with the pump system comprising a magnetically levitated turbopump that is arranged in the pump system directly adjoining the process volume.

The pump system can be further developed as described above. The coatings described above can be deposited onto the substrates with less contamination by means of such a pump system.

In accordance with a second aspect of the invention, the object is satisfied by a process chamber for a coating apparatus for coating a substrate of a substrate material with at least one material layer of a layer material. A process chamber in accordance with the invention is characterized in that the process chamber is configured for a use in a coating apparatus in accordance with the first aspect of the invention. A process chamber in accordance with the invention in accordance with the second aspect of the invention is provided for a use in a coating apparatus in accordance with the first aspect of the invention. In other words, a process chamber in accordance with the invention in accordance with the second aspect of the invention can be used in or by or with a coating apparatus in accordance with the first aspect of the invention. Thus, all the advantages and features that have been described in detail above with respect to a coating apparatus in accordance with the first aspect of the invention can also be provided in conjunction with a process chamber for a coating apparatus in accordance with the second aspect of the invention. A process chamber in accordance with the second aspect of the invention can in particular preferably have at least one, in particular a plurality of, preferably all, of the features that have already been described above with respect to a process chamber of a coating apparatus in accordance with the invention in accordance with the first aspect of the invention.

In accordance with a third aspect of the invention, the object is satisfied by a method of coating a substrate of a substrate material with at least one material layer of a layer material in a coating apparatus in accordance with the first aspect of the invention. A method in accordance with the invention is characterized in that a source material is used for at least partly providing the layer material, said source material being heated and being thermally evaporated and/or sublimated below a plasma generation threshold of the source material by a continuous or at least substantially continuous laser light of a source heating laser. A method in accordance with the invention in accordance with the third aspect of the invention is carried out in a coating apparatus in accordance with the first aspect of the invention. Thus, all of the advantages that have been described in detail above in connection with a coating apparatus in accordance with the first aspect of the invention can also be provided in connection with a method of coating a substrate in accordance with the third aspect of the invention.

In accordance with the invention, these advantages can be provided in that a source material is used for at least partly providing the layer material, said source material being heated by a continuous or at least substantially continuous laser light of a source heating laser of the coating apparatus and being thermally evaporated and/or sublimated below a plasma generation threshold of the source material. Due to the continuous or at least substantially continuous irradiation of the laser light onto the source material, provision can in particular be made that a temperature of the source material varies by less than 30%, preferably by less than 10%. A continuous or at least substantially continuous evaporation rate and/or sublimation rate of source material can thereby in turn be provided. Due to the use of laser light with an energy below a plasma generation threshold of the source material, a purely thermal evaporation and/or sublimation of the source material, which takes place below the plasma generation threshold of the source material, can further be ensured. This laser light is preferably coupled into a process volume of the coating apparatus via a coupling-in apparatus or its coupling-in section, whereby electrical apparatus for heating the source material can be omitted in the interior of the process volume. All the restrictions that are caused by such electrical components in the interior of the process volume, for example with respect to a selection of a process gas used and/or of a pressure level of the coating atmosphere, can be prevented in this way.

In a method in accordance with the invention, provision can particularly preferably be made that the source material is directly heated and thermally evaporated and/or sublimated by the laser light by a direct irradiation of the laser light onto a source surface of the source material. A particularly good transfer of energy from the laser light of the source heating laser into the source material, in particular, for example, without an intermediate heating of a source crucible receiving the corresponding source material, can thus be provided. In this way, it is additionally ensured that the source surface represents one of the hottest points in the process volume. In this way, a purity of the source material can be provided throughout the total coating process.

The method in accordance with the invention can also be designed in that the substrate material of the substrate is heated by laser light of a substrate heating laser, in particular is directly heated by a direct irradiation, with preferably laser light being used that is adapted to the substrate material and/or that has an intensity of 0.01 W to 50 kW and/or a wavelength of 10⁻⁶ m to 10⁻⁴ m.

In a method in accordance with the invention, a substrate heating, as it is provided by the light beam of laser light of the substrate heating laser, makes it possible in a method in accordance with the invention that, analogously to the source material, the substrate material can also be heated without electrical components having to be present in the process volume, with all the advantages already described with respect to the heating of the source material. Provision can also be made that, in addition to the source material, the substrate itself can be formed as one of the hottest locations in the process volume. A production of a coating of the substrate with a layer material of particular purity can be provided in this way.

A heated substrate furthermore also enables a particularly uniform growth of the material layer since the evaporated layer material can extract kinetic energy from the heated substrate in order to distribute itself as uniformly as possible on the substrate surface.

A laser having a longer wavelength than the source heating laser is preferably used as the substrate heating laser since the substrates that are usually used correspondingly have different absorption properties than the source materials. Thus, a long wavelength laser of, for example, a wavelength of 10.6 μm can, for example, be used for a substrate that is a ceramic and/or itself is an oxide. A CO₂ laser can in particular, for example, be used as a substrate heating laser for visibly transparent substrate materials.

Furthermore, in a method in accordance with the invention, provision can be made that a coating atmosphere having a pressure between 10⁻¹⁰ mbar and 1 mbar, preferably less than 10⁻³ mbar, is provided in the process volume by the gas system of the coating apparatus.

As described above, electrical apparatus for heating the source material can be omitted in the interior of the process volume due to the use of laser light for heating and thermally evaporating and/or sublimating the source material. In this way, it is possible to generate a coating atmosphere in the process volume independently and depending on the desired layer material to be produced, wherein the corresponding pressure of the coating atmosphere can in particular also be suitably set to the layer material to be produced over a wide range, in particular between 10⁻¹⁰ mbar and 1 mbar. A particularly versatile and adapted coating atmosphere, in particular with respect to its pressure level, can be provided in this way.

The pressure level can preferably, for example, be set to a mean free path length of the thermally evaporated and/or sublimated source materials in the process volume, for example a pressure level of approximately 10⁻² mbar at a distance of 60 mm between the source surfaces of the source materials and the substrate to be coated.

This has the further advantage that an evaporation of the coupling-in section, in particular, for example, an occupation of the inlet window, is additionally reduced since source material particles are scattered a multiple of times at the process gas before the reaching of the coupling-in section or of the inlet window and are thus no longer directed in a concentrated manner, but rather impact there in a homogenous manner averaged over the total inner side of the chamber wall of the process chamber or are also pumped out of the process chamber together with the process gas.

Furthermore, a method in accordance with the invention can be designed in that the gas system of the coating apparatus provides a coating atmosphere having a gaseous substance adapted to the layer material of the material layer as the process gas, in particular having molecular oxygen and/or ozone and/or nitrogen and/or gaseous selenium compounds and/or gaseous sulfur compounds as the process gas, in the process volume.

In general and in principle, all the gaseous substances can be considered as the process gas. In the sense of the invention, any residual gas that remains in the process volume on a provision of low pressures in the range of 10⁻³ mbar or lower is in particular also understood as the process gas provided by the gas system.

A production of some layer materials for material layers for coating the substrate can be promoted or even made possible at all by a corresponding selection of a process gas. Thus, molecular oxygen and/or ozone can, for example, make it possible as part of the process gas to produce oxides as the layer material of the material layer since the oxidation processes necessary for the formation of the oxides require this oxygen that can be provided by molecular oxygen and/or ozone.

Analogously, a formation of nitrides as the layer material can also be made possible by a provision of nitrogen, both molecular nitrogen and ionized nitrogen. Gaseous selenium compounds and/or sulfur compounds represent highly reactive process gases that can, for example, be used in the production of solar cells. It is also advantageous for these highly reactive and aggressive process gases that electrical components in the interior of the process volume, and thus exposed to the highly reactive process gases of the coating atmosphere, can be omitted due the use of light beams of a source heating laser for the heating and thermal evaporation and/or sublimation of the source material.

In a method in accordance with the invention, provision can particularly preferably be made that an oxide having a perovskite structure, in particular an oxide that is doped with at least one doping element and that has a perovskite structure, is produced as the layer material, the oxide comprising a first metal element and a second metal element, with the first metal element and the second metal element, in particular also the at least one doping element, being provided as the source material, preferably being provided as a solid, cylindrical piece, or in a respective one source crucible, and molecular oxygen and/or ozone being used as the process gas in the coating atmosphere.

Overall, all solid or liquid elements and substances can generally be considered as source material for the material synthesis by means of thermal laser evaporation, wherein the evaporation can also take place as sublimation from the solid phase, and wherein all gaseous substances can simultaneously be used for the process gas used.

Furthermore, all the solid and liquid elements, compounds and mixtures of substances can thus be produced as the layer material by a method in accordance with the invention. It is in particular possible by a method in accordance with the invention to produce material layers having epitaxially oriented, crystalline solids as the layer material.

In a specific embodiment, the first metal element can, for example, comprise strontium; the second metal element can, for example, comprise titanium; and, if used, the doping element can comprise niobium.

A strontium titanate doped with niobium and comprising strontium as the first metal element, titanium as the second metal element, and niobium as the doping element can in particular be produced as the oxide.

Complex oxides such as strontium titanate are particularly difficult to produce by means of MBE. This is in particular due to the fact that a process gas through which oxidation processes that are necessary for the formation of the oxides can take place, for example oxygen and/or ozone, is usually required as the coating atmosphere. In PLD, such oxides having a perovskite structure can indeed generally be produced as layer materials, but it is often not possible to provide the specifically desired stoichiometry of the respective oxide due to the ablation that represents the core of PLD.

This is in particular due to the fact that an oversupply of a more volatile component of the oxide is often required for this purpose. As already described above, a doping of such an oxide having a perovskite structure can in particular only be provided with difficulty by PLD, wherein a modulated and/or variable doping is impossible or at least substantially impossible with PLD as the coating method. Due to the use of a method in accordance with the invention, such an oxide having a perovskite structure can be produced as the layer material, in particular also with a variable doping.

This is in particular due to the fact that, on the one hand, the necessary control over the stoichiometry on the production of the material layer can be provided by the thermal evaporation and/or sublimation of the source materials with a variable temperature, and a possible switching in or out of the individual source materials by rapidly varying the individual source laser powers, or corresponding shutter covers. On the other hand, electrical components can simultaneously be omitted in the process volume and thus in the coating atmosphere due to the use of light beams of a source heating laser for a heating and thermal evaporation and/or sublimation of the source material, whereby restrictions in the selection of the parameters of the coating atmosphere can at least largely be avoided and they can thus be selected and set ideally adapted to the oxide to be produced, both with respect to a process gas used and a pressure level set. Furthermore, growth can take place under absorption-controlled conditions, in which the ideal material composition results in a self-adjusting manner from an oversupply of the volatile component of the compound to be deposited at finite desorption. Instead of one, there can also be a plurality of volatile components that can not only comprise elements, but also compounds. Even all the components of the layer to be deposited can in particular be volatile so that the process can be run arbitrarily close to equilibrium, i.e. to the point at which a deposition of material on the surface begins in the first place. This is interesting for layers of pure elements (e.g. graphene) or compounds (so-called 2D materials such as boron nitride), in which the first nucleation should take place as slowly as possible so that the individual two-dimensional crystals arising therefrom become as large as possible.

In summary, a material that is arbitrary in principle, such as an oxide having a perovskite structure, can thus be provided as the layer material for coating a substrate by a method in accordance with the invention, in particular by the use of a method in accordance with the invention in a coating apparatus in accordance with the invention, wherein a doping of this material or oxide, preferably also a variable and/or modulated doping, can in particular also be made possible. Strontium titanate, in particular having a modulated niobium doping, represents a particular example of such an oxide.

In accordance with a fourth aspect of the invention, the object is satisfied by a substrate coated with at least one material layer, comprising the substrate of a substrate material that is coated with at least one material layer of a layer material. A coated substrate in accordance with the invention is characterized in that the substrate coated with at least one material layer is produced in a coating apparatus in accordance with the first aspect of the invention and/or using a method in accordance with the third aspect of the invention. A production of a coated substrate in accordance with the invention in accordance with the fourth aspect of the invention thus takes place using a coating apparatus in accordance with the first aspect of the invention and/or using a method of coating a substrate in accordance with the third aspect of the invention. Thus, all the advantages and features that have been described in detail above with respect to a coating apparatus in accordance with the first aspect of the invention or with respect to a method in accordance with the third aspect of the invention can also be provided in connection with a coated substrate in accordance with the fourth aspect of the invention.

Further features and advantages of the invention will be described in the following with reference to Figures. Elements with the same functionality and mode of operation are provided with the same reference numerals in the individual figures. There are schematically shown:

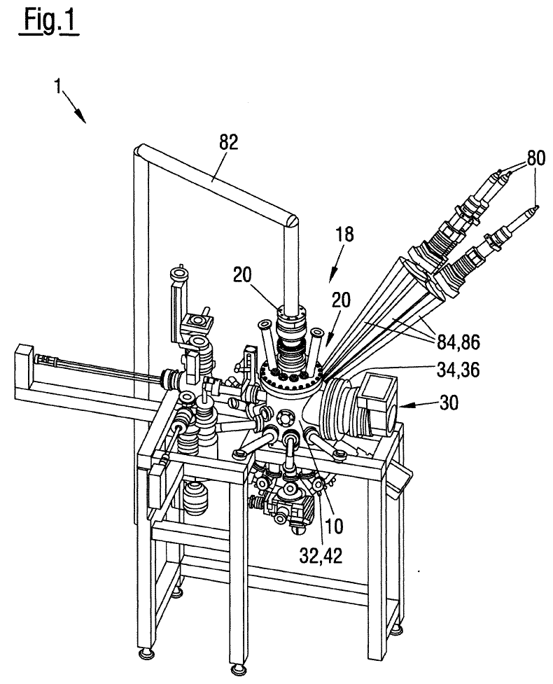

FIG. 1 a coating atmosphere in accordance with the invention;

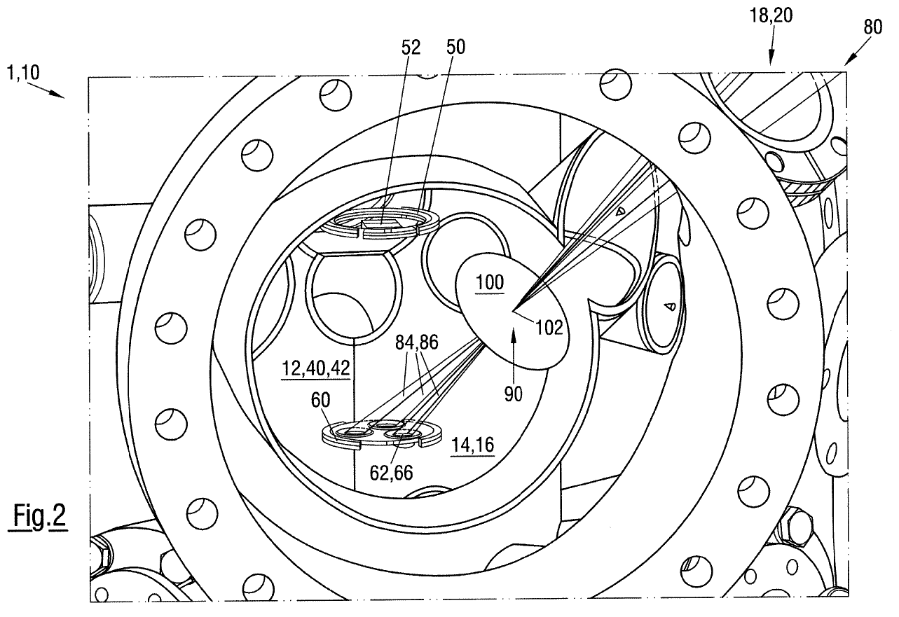

FIG. 2 a process chamber of a coating apparatus in accordance with the invention;

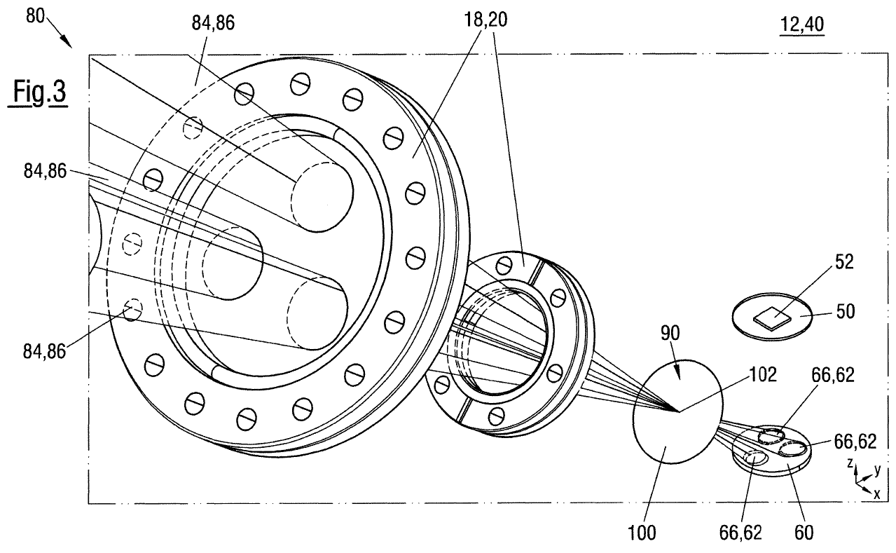

FIG. 3 a first embodiment of a laser radiation;

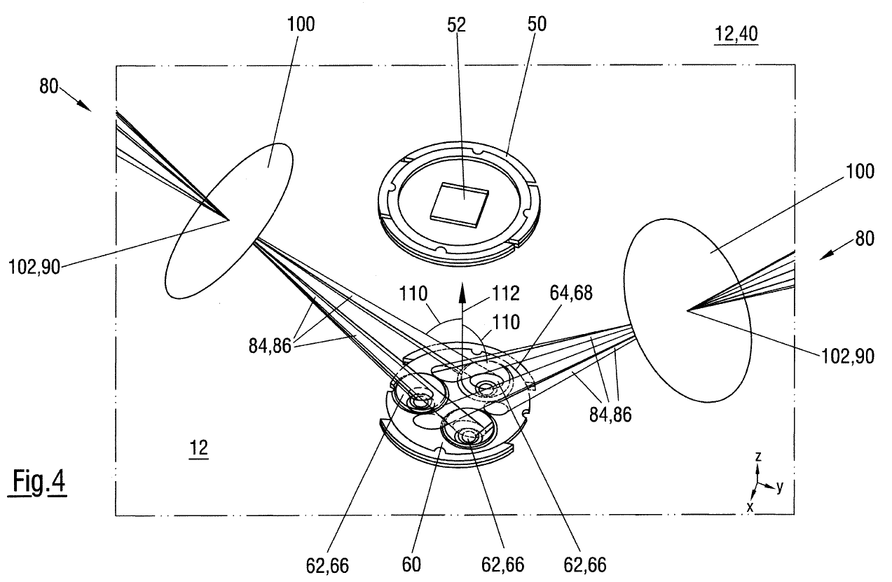

FIG. 4 a second embodiment of a laser radiation;

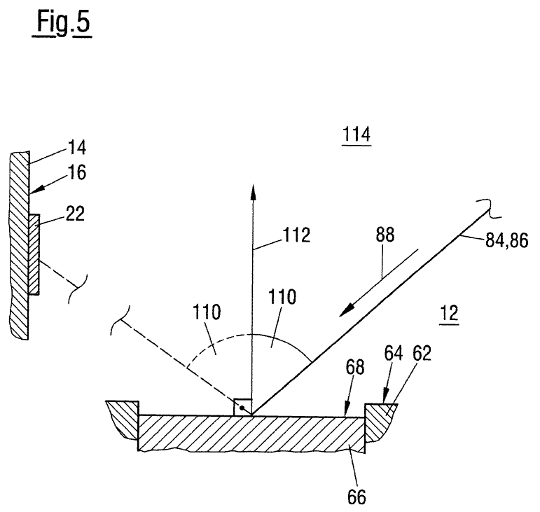

FIG. 5 a third embodiment of a laser radiation;

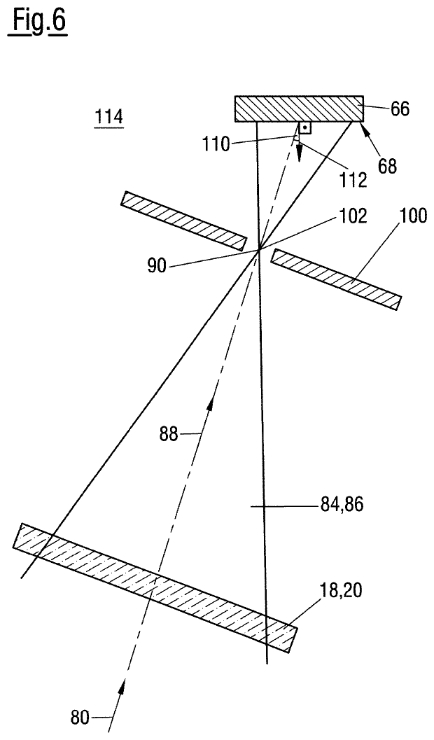

FIG. 6 a light beam having a heating beam aperture;

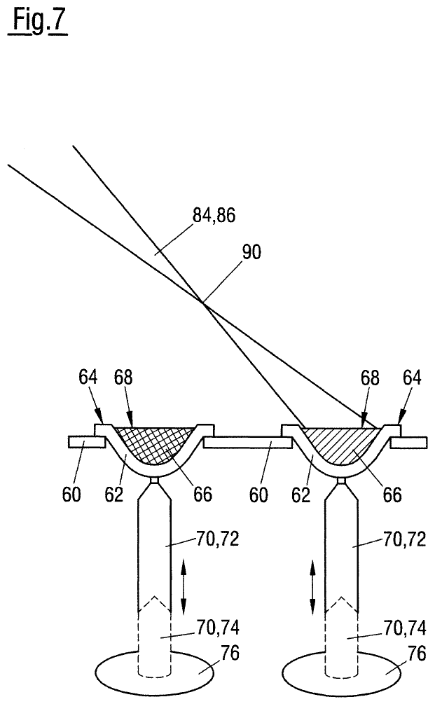

FIG. 7 a source holder;

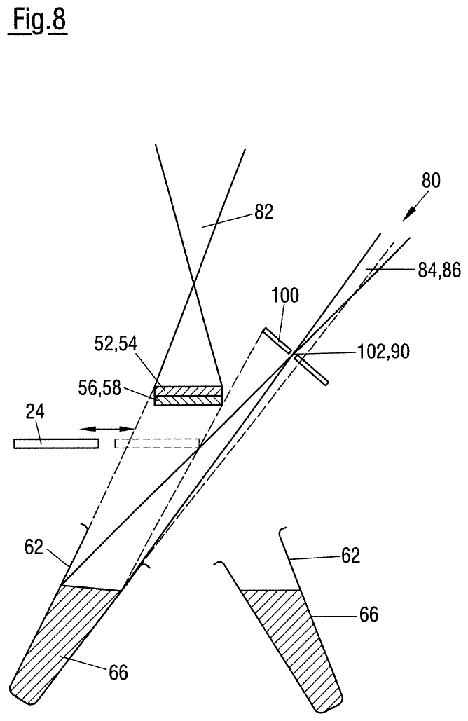

FIG. 8 a special source crucible design; and

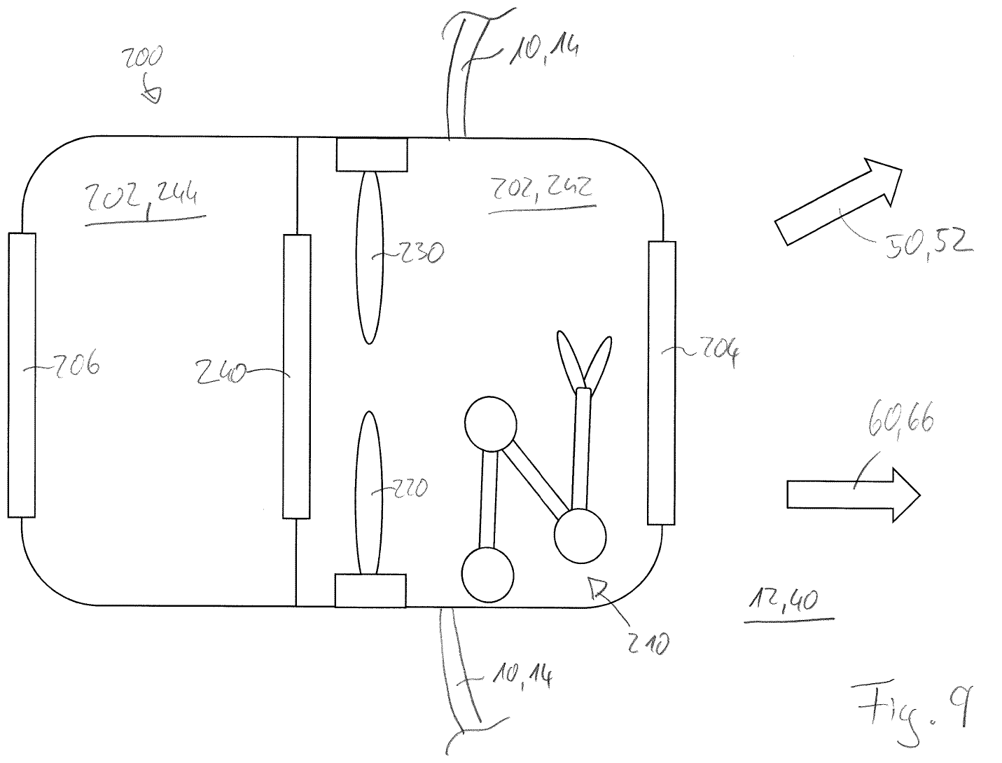

FIG. 9 a sealable lock in the chamber wall of the process chamber.

FIG. 1 shows the substantial outer design of a coating apparatus 1 in accordance with the invention that is configured to carry out a method in accordance with the invention. Thus, the coating apparatus 1 in accordance with the invention in particular comprises a process chamber 10, preferably a process chamber 10 in accordance with the invention, that forms the core of the system. The coating process, not visible in this Figure, takes place in the interior of the process chamber 10. A possible internal design of a process chamber 10, in particular a process chamber 10 in accordance with the invention, or of the process volume 12 (not shown) is shown in FIG. 2. A gas system 30 provides a coating atmosphere 40 (not shown) in the interior of the process chamber 10. For this purpose, the gas system 30 in particular has a process gas supply 32 through which a process gas 42 can be conducted into the interior of the process chamber 10. A pump system 34, in particular having a magnetically levitated turbopump 36 arranged directly adjoining the process chamber, generates the necessary pressure level in the interior of the process chamber 10. In particular pressure levels over a wide range of pressures can preferably be provided by a pump system in accordance with the invention, for example having a pressure between 10⁻¹⁰ mbar and 1 mbar, preferably less than 10⁻³ mbar.

Further, as depicted in FIG. 1, the process chamber 10 can preferably comprise a monolithic chamber body, in particular made form aluminum or aluminum alloy. Said chamber body completely provides the chamber wall 14 enclosing the process volume 12. An optional cooling means (not shown) can also be implemented for cooling the process volume 12 by cooling the chamber body. Preferably, coolant ducts of the cooling means can directly be integrated in the chamber body. In particular, in some embodiments the cooling means can also provide heated fluid through its coolant ducts, thereby effectively heating the process volume 12.

In a manner essential to the invention, provision is made in a coating apparatus 1 in accordance with the invention that the source material 66 (not shown) can be heated and thermally evaporated and/or sublimated by light beams 86 of laser light 84 of a source heating laser 80. The at least one source heating laser 80 is in particular an element of the coating apparatus 1 in accordance with the invention. This laser light 84, shown split into three light beams 86 here, can be conducted into the interior of the process chamber 10 via a coupling-in section 20 of a coupling-in apparatus 18.

A substrate heating laser 82 is further shown by which, likewise coupled in via a coupling-in section 20 of the coupling-in apparatus 18, a substrate 52 (not shown) can be heated in the interior of the process chamber 10. Due to the use of externally supplied laser light 84, provision can in particular be made that electrical components can at least substantially be omitted in the interior of the process chamber 10.

Restrictions with respect to a pressure of the coating atmosphere 40 or a selection of the process gas 42 that are caused by these electrical components, such as are required for MBE, can in this way be avoided in a coating apparatus 1 in accordance with the invention. Thus, coating atmospheres 40 having the wide pressure range of 10⁻¹⁰ mbar to 1 mbar already listed above can, for example, be used, wherein highly corrosive process gases 42 such as molecular oxygen and/or ozone and/or nitrogen and/or gaseous selenium compounds and/or gaseous sulfur compounds can also be used at least substantially without limitation. This, for example, enables a provision of oxides having a perovskite structure also and in particular having a modulated doping, for example strontium titanate having a modulated niobium doping.

FIG. 2 shows, by way of example, a design in the interior of the process chamber 10 and thus of the process volume 12 of a coating apparatus 1 in accordance with the invention. The process chamber 10, in particular its chamber wall 14, forms the process volume 12 in which the coating atmosphere 40, comprising a process gas 42 at a certain pressure level, is arranged.

The chamber wall 14 can, as shown here, be of multilayer design, whereby a cooling plate is formed within the process chamber 10 or the vacuum, said cooling plate, for example, being filled with liquid nitrogen during operation and thus being able to be cooled to approximately 77 K. This cooling plate, as in the prior art of MBE, forms a thermal shield and reduces the partial pressures of unwanted elements and compounds in the residual gas or the coating atmosphere 40 by freezing out impurities.

The inner side 16 of the chamber wall 14 at least substantially completely encloses the process volume 12, wherein feedthroughs through the chamber wall 14 are closed and sealed to bound and hold the coating atmosphere 40 in the process volume 12. A substrate holder 50 having a substrate 52 is arranged in the interior of the process volume 12. Furthermore, a source holder 60 is arranged in the interior of the process volume 12 and, as shown, can hold a plurality of source crucibles 62 that preferably have different source materials 66. In alternative or additional embodiments of a coating apparatus 1 in accordance with the invention, not shown in FIG. 2, suitable source materials 66 can also be arranged without source crucibles 62 in the source holder 60, for example in bar-shaped and/or rod-shaped embodiments. Independent of the actual embodiment, each of the at least one source materials 66 is provided as a pure chemical element.

The source heating laser 80 of the coating apparatus 1 in accordance with the invention is further shown, whose three light beams 86 of laser light 84 are associated with the individual source materials 66 in the source crucibles 62 and preferably irradiate them directly and immediately to heat and thermally evaporate and/or sublimate them. In particular, a continuous or at least substantially continuous separate light beam 86 of laser light 84 is provided for each of the at least one elemental source materials 66.

In this respect, the source heating laser 80 is configured to continuously or at least substantially continuously provide laser light 84. This makes it possible to irradiate the respective laser light 84 continuously or at least substantially continuously onto the corresponding source material 66, in particular to provide a particularly constant and controllable or adjustable energy input of the laser light 84 into the corresponding source material 66. A constant and/or controllable and adjustable temperature of the respective source material 66, and thus a resulting evaporation rate and/or sublimation rate, can be made possible in this manner. Furthermore, an energy of the laser light 84 of the source heating laser 80 is set such that a plasma generation threshold of the source material 66 is not reached by the laser light 84. In other words, no plasma is generated on the incidence of the laser light 84 on the source material 66. A purely thermal evaporation and/or sublimation of the respective source material 66 can thereby be ensured.

As shown, the substrate holder 50 and the source holder 60 can preferably be arranged directly opposite one another, whereby a particularly good evaporation and/or sublimation of the source material 66 or evaporation of the source material 66 onto the substrate 52 can take place.

Furthermore, an intensity and/or a wavelength of the respective laser light 84 can preferably be adapted to the corresponding source material 66 to further improve the heating and in particular the thermal evaporation and/or sublimation of the respective source material 66. Parameters of the laser light 84 can, for example, be an intensity from 0.01 W to 50 kW and/or a wavelength from 10⁻⁸ m to 10⁻⁵ m.

A particularly good adaptation of the respective laser light 84 used to the corresponding source material 66 can thereby be provided. The light beams 86 can furthermore have a focal area 90 that, as shown, can preferably also overlap for the individual light beams 86. A heating laser aperture 100 having an aperture opening 102 is arranged adapted to this overlapping focal area 90.

In this respect, provision can preferably again be made that the aperture opening 102 has been introduced into the heating laser aperture 100 by the light beam 86 of the source heating laser 80 itself. As can clearly be seen, the heating laser aperture 100 can be arranged between the source holder 60 and the coupling-in section 20 of the coupling-in apparatus 18, whereby an impact of evaporated and/or sublimated source material 66 on the coupling-in section 20 can be reduced or even completely avoided.

This arrangement is furthermore also shown in FIG. 3 in which the three light beams 86 of laser light 84 are even better recognizable. Furthermore, it is clearly recognizable in FIG. 3 that the three light beams 86 can be introduced into the process volume 12 or into the coating atmosphere 40 by a common coupling-in section 20 of the coupling-in apparatus 18. It is also clearly recognizable that the direct path between the source holder 60 and the coupling-in section 20 is covered by the heating laser aperture 100 except for the small region of the aperture opening 102. Evaporated and/or sublimated material of the source material 66 is thus completely or at least substantially completely deposited on the heating laser aperture 100 and does not reach up to the coupling-in section 20.

FIG. 4 shows an alternative embodiment in which, in contrast to FIG. 3, six different positions for source materials 66 are now provided on the source holder 60, but only three of them are occupied by source materials 66 in source crucibles 62 in the Figure shown. Provision is now made for the irradiation of the source crucibles 62 in each case by a separate light beam 86 of laser light 84 that these light beams 86 irradiate onto the source holder 60 from two different sides. This can be made possible in that the coupling-in apparatus 18 has two mutually separate coupling-in sections 20 (not shown).

Each of these triples of light beams 86 of laser light 84 of the source heating laser 80 in turn has a common focal region 90 at which the aperture opening 102 of a heating laser aperture 100 is correspondingly in each case arranged again.

In this way, the substrate 52 in the substrate holder 50 can overall again be arranged opposite to and in parallel with the source materials 66 in the source holder 60 and can furthermore be coated with a wide range of different source materials 66. A substrate 52 in accordance with the invention that is coated with at least one material layer 56 (cf. FIG. 8) can in particular be produced using a coating apparatus 1 in accordance with the invention and/or using a method in accordance with the invention.

Thereby, if a material layer 56 consisting of a layer material 58 (see FIG. 8) comprising only a single chemical element as constituent is aimed at, an extremely high purity of the deposited layer material 58 can be achieved, preferably further supported by using a high vacuum (pressure 10⁻³-10⁻⁸ hPa) or even ultrahigh vacuum (pressure 10⁻⁸-10⁻¹¹ hPa) as coating atmosphere 40. Alternatively, if a layer material 58 comprising two or more chemical elements as constituents, namely a compound, is aimed at, each of the chemical elements needed for said layer material are provided separately, either as a separate source material 66 or by the coating atmosphere 40. In this case, an extremely high purity of the deposited layer material 58 can also be achieved due to the pureness of the initial materials.

Preferably, the surface of the substrate 52 is prepared such that the compound is formed only on said surface of the substrate. This can for instance be provided by heating the substrate 52 by the substrate heating laser 82. this is one of the main differences of TLE described in the present invention compared to PLD known in the state of the art. By preparing the surface of the substrate, i.e. by altering the chemical and/or physical properties, the forming of the compound on the surface of the substrate 52 can be supported or even rendered possible in the first place. Also, this measure helps increasing the purity of the deposited compound, and hence of the layer material 58.

In particular, the heating of the substrate 52 described in the previous paragraph even allows an adsorption-controlled way of depositing the layer material 58 onto the surface of the substrate 52. The evaporated and/or sublimated at least one source material 66 is provided in abundance, but due to the heating of the substrate 52 desorbs from the substrate 52 if not incorporated into the compound forming the layer material 58, as long as it is not accompanied by the remaining chemical elements needed for forming the compound aimed at as layer material 58. This is especially of advantage if the layer material 58 has a higher desorption temperature than said source material 66. This leads to an adsorption-controlled way of depositing the layer material 58 onto the surface of the substrate 52. An especially versatile control of the deposition process can thereby be provided.

As shown, the two coupling-in sections 20 of the coupling-in apparatus 18 can preferably be arranged such that the spatial planes 114 (not shown), which the respective light beam 86, which is conducted into the process volume 12 by one of the separate coupling-in sections 20, and the surface normal 112 to the crucible surface 64 of the corresponding source crucible 62 and/or to the source surface 68 of the corresponding source material 66 span, enclose an angle of less than 180°, preferably between 90° and 150°, particularly preferably of 120°.

For a better overview, only one crucible surface 64 or one source surface 66 and only one of the surface normals 112 are shown. A reflection of a light beam 86 coming from one coupling-in section 20 to the other coupling-in section 20 can thereby be avoided.

A source crucible 62 with arranged source material 66 is likewise schematically shown in FIG. 5. A light beam 86 of a laser light 84 is conducted into the process volume 12 such that it is incident on the source surface 68 of the source material 66 or, if correspondingly widened, on a crucible surface 64 of the source crucible 62 at an angle of incidence 110, in particular an angle of incidence 110 between 30° and 70°, preferably 50°. As already described with respect to FIG. 4, it can happen that the laser light 84 is reflected, as is indicated by dashed lines in FIG. 5.

To prevent a heating of a chamber wall 14 by the reflected laser light 84, a beam catcher 22 is arranged at an inner side 16 of the chamber wall 14. The arrangement location of the beam catcher 22 is in particular preferably disposed in a spatial plane 114 that is spanned by the surface normal 112 and the light direction 88 of the laser light 86. Furthermore, the arrangement location is determined in accordance with the angle of incidence 110 that is at least substantially also the angle of reflection. A heating of the chamber wall 14 and thereby a possible source of contamination in the interior of the process volume 12 can be avoided by the beam catcher 22 that can also be designed as cooled.

FIG. 6 shows a schematic representation of the light beam 86 of laser light 84, coming from the source heating laser 80, again in the spatial plane 114 that has already been described in FIG. 5. It is particularly clearly visible that the light beam 86 has its smallest extent at the focal area 90 perpendicular to the light direction 88. Accordingly, the aperture opening 102 of the heating laser aperture 100 is arranged at this focal area 90. Source material 66 that is evaporated and/or sublimated by the irradiated laser light 84 is thus almost completely captured by the heating laser aperture 100 and thus cannot reach the coupling-in section 20 of the coupling-in apparatus 18. A service life of the coupling-in section 20, in particular a coupling-in window as part of the coupling-in section 20, can be extended in this way.

Possible embodiments of source crucibles 62 in a source holder 60 are shown in FIG. 7. The two source crucibles 62 are each filled with a different source material 66, wherein one of the source materials 66 is directly and immediately irradiated, heated, and thermally evaporated and/or sublimated by a light beam 86 of laser light 84 of a source heating laser 80. A temperature of the respective source material 66 can be determined by a thermocouple 70 in its measurement position 72. For a movement, for example a replacement, of the source holder 60, the thermocouples 70 can have a movable fastening section 76, whereby the thermocouples 70 can be moved from their measurement position 72 into a release position 74. An impediment of a movement of the source holder 60 by the thermocouples 70 can be avoided in this way. Alternatively or additionally, a mechanism can also be provided in which the thermocouples 70 are fixedly, or substantially fixedly, fastened in the measurement position 72 and the releasable contact with the lower sides of the source crucibles 62 is achieved by lowering or raising the source holder 60 on a transfer (not shown).

FIG. 8 now shows an alternative embodiment of source crucibles 62 and source material 66 arranged therein. In contrast to the source crucibles shown in FIG. 7, these source crucibles 62 are formed with larger depth in FIG. 8. A correspondingly larger amount of source material 66 can be arranged in these alternative source crucibles 62.

In FIG. 8, a shutter cover 24 is likewise shown by which, as shown in dashed lines, evaporated and/or sublimated source material 66 can be captured and an evaporation of the substrate material 54 of the substrate 52 can thereby be switched on or switched off. The layer material 58 of the material layer 56, which is produced on the substrate material 54 of the substrate 52 in a coating apparatus 1 in accordance with the invention (not shown) or by a method in accordance with the invention, can in this way be controlled particularly well and stoichiometrically precisely. A substrate heating laser 82 by which the substrate 52 can be heated or heated up is furthermore shown in FIG. 8. Furthermore, the source heating laser 80 having a light beam 86 of laser light 84 and a heating laser aperture 100 having an aperture opening 102 are also again shown.

FIG. 9 schematically depicts a possible embodiment of a sealable lock 200 comprising a lock volume 202 arranged in the chamber wall 14 of the reaction chamber 10. Said sealable lock 200 allows access to the process volume 12, wherein breaking the coating atmosphere 40 can be avoided.

For this purpose, the sealable lock 200 comprises a first lock door 204, which opens towards the process volume 12, and a second lock door 206, which opens towards the environment surrounding the process chamber 10. Both lock doors 204, 206 are sealable, allow access to the lock volume 202, and can be operated independently from each other. Further, the lock volume 202 is divided by a divider 240 in a first compartment 242 and a second compartment 244. The first compartment 242 extends between the divider 240 and the first lock door 204, the second compartment 244 extends between the divider 240 and the second lock door 206. The lock volume 202 is connected to the gas system 30 (see FIG. 1) for altering the atmosphere within the lock volume 202. Preferably, both compartments 242, 244 are connected separately with the gas system 30, allowing different atmospheres within the two compartments 242, 244.

Within the lock volume 202, in particular in the first compartment 242, an exchange mechanism 210 is arranged. Said exchange mechanism 210 is constructed to exchanging the at least one source material 66, and in the depicted embodiment also the substrate 52. In other words, the exchange mechanism 210 is constructed to grab the respective item, source material 66 or substrate 50, and move it within the process volume 12, and with the first lock door 204 opened, also into the lock volume 202. The respective position of the source holder 60, at which the source material 66 is arranged within the process volume 12, and of the substrate holder 50, at which the substrate 52 is arranged within the process volume 12, respectively, are indicated in FIG. 9 by arrows.

In the following, an arrangement of a source material 66 or of a substrate 52 into the process volume 12 is described. Removing one of these items from the process volume 12 is done accordingly in a vice versa order of steps.

For removing the source materials 66 or the substrate 52, respectively, first of all said source material 66 or substrate 52 is placed within the lock volume 202, in particular in the first compartment 242 through the open second lock door 206 and the open divider 240, while the first lock door 204 is closed and sealed. As depicted, for arranging the source material 66 and the substrate 52 within the lock volume 202, preferably a source holding structure 22 or a substrate holding structure 230 can be provided, especially in the first compartment 242.

Afterwards, both lock doors 204, 206 and the divider 240 are closed and sealed, and the atmosphere within the lock volume 202, especially in the first compartment 242, is equalized to the coating atmosphere 40 in the process volume 12. After that, the first lock door 204 is opened, and subsequently the exchange mechanism 210 is used for grabbing the respective source material 66 or the substrate 52, moving it out of the lock volume 202 towards its destination within the process volume 12, namely the source holder 60 or the substrate holder 50, respectively. After that, the first lock door 204 is closed.

It is to be noted that if more than one source material 66 or several substrates 52 should be exchanged, the exchange mechanism 210 can preferably be constructed for grabbing and moving all of them at once.

The present disclosure also relates to the following first set of enumerated embodiments:
1. A coating apparatus for coating a substrate of a substrate material with at least one material layer of a layer material, said coating apparatus comprising a process chamber having a process volume for receiving a substrate holder for arranging the substrate, wherein the substrate holder is arranged in a fixed position in the process volume such that the substrate holder can furthermore be provided rotatable and/or movable essentially in a plane normal to the deposition direction as a whole,
   wherein the process chamber has a chamber wall for at least substantially completely enclosing the process volume; a gas system connected in a fluid-communicating manner to the process volume for generating a coating atmosphere in the process volume; and a source holder arranged in the process volume and having at least one source material, wherein the source holder and the substrate holder are further arranged relative to one another such that thermally evaporated and/or sublimated source material can be deposited on the substrate for an at least partial formation of the layer material of the material layer, said coating apparatus further comprising a source heating laser,
   wherein the source heating laser is configured to provide a continuous or at least substantially continuous separate beam of laser light and the process chamber has a coupling-in apparatus having at least one coupling-in section in the chamber wall for conducting laser light of a source heating laser into the process volume for thermally evaporating and/or sublimating the at least one source material below a plasma generation threshold,
   wherein the process chamber comprises a monolithic chamber body providing the whole chamber wall.
2. The coating apparatus in accordance with embodiment 1,
   wherein the chamber body consists of aluminum or of an aluminum alloy.
3. The coating apparatus in accordance with embodiment 1,
   wherein the process chamber comprises cooling means for a fluid cooling of the process volume.
4. The coating apparatus in accordance with embodiment 3,
   wherein the cooling means comprise coolant ducts, wherein further the coolant ducts are at least partly integrated in the chamber body.
5. The coating apparatus in accordance with embodiment 1,
   wherein each of the at least one source materials is provided as a pure chemical element.
6. The coating apparatus in accordance with embodiment 5,
   wherein the layer material is a compound comprising two or more chemical elements, wherein at least one of the two or more chemical elements originates from one of the at least one source materials.
7. The coating apparatus in accordance with embodiment 6,
   wherein the coating atmosphere comprises a reaction gas, wherein at least one of the two or more chemical elements of the layer material originates from the reaction gas.
8. The coating apparatus in accordance with embodiment 6,
   wherein a surface of the substrate is prepared such that the compound is formed only on the surface of the substrate.
9. The coating apparatus in accordance with embodiment 8,
   wherein the apparatus comprises a substrate heating laser for heating the substrate,
   wherein the substrate heating laser is constructed for heating the substrate such that at least one chemical element of the compound forming the layer material desorbs from the substrate if not incorporated into the compound forming the layer material.
10. The coating apparatus in accordance with embodiment 1,
   wherein the process chamber comprises an airtight sealable lock with a lock volume, wherein the lock comprises a first lock door sealable against the process volume and a second lock door sealable against the environment, the process chamber further comprising an exchange mechanism for exchanging the at least one source material, wherein the exchange mechanism is constructed to operate within the process volume and to grab and move the at least one source material between the source holder and the lock volume.
11. The coating apparatus in accordance with claim 10,
   wherein the exchange mechanism is arranged within the lock volume.
12. The coating apparatus in accordance with claim 10,
   wherein the lock comprises a divider for dividing the lock volume a first compartment and a second compartment sealable to each other by the divider,
   wherein the first compartment extends between the divider and the first lock door, and the second compartment extends between the divider and the second lock door.
13. The coating apparatus in accordance with embodiment 10,
   wherein the lock comprises a source holding structure arranged in the lock volume,
   wherein the source holding structure is constructed to receive the at least one source material placed in the lock volume by the exchange mechanism.
14. The coating apparatus in accordance with embodiment 10,
   wherein the exchange mechanism is constructed to grab and move all source materials simultaneously.
15. The coating apparatus in accordance with embodiment 10,
   herein the exchange mechanism is constructed to also grab and move the substrate between the substrate holder and the lock volume.
16. The coating apparatus in accordance with embodiment 15,
   wherein the lock comprises a substrate holding structure arranged in the lock volume, wherein the substrate holding structure is constructed to receive the substrate placed in the lock volume by the exchange mechanism.
17. The coating apparatus in accordance with embodiment 1,
   wherein the source material can be directly heated and thermally evaporated and/or sublimated by the laser light by a direct irradiation of the laser light onto a source surface of the source material.
18. The coating apparatus in accordance with embodiment 1,
   wherein the light beam encloses an angle of incidence between 0° and 90° with a surface normal to a crucible surface of the source crucible having source material and/or with a surface normal to a source surface of the source material.
19. The coating apparatus in accordance with embodiment 1,
   wherein at least one of an intensity and a wavelength of the laser light is adapted to the corresponding source material.
20. The coating apparatus in accordance with embodiment 1,
   wherein the process chamber has, at an inner side of the chamber wall, at least one beam catcher for at least partly absorbing reflected laser light, with the beam catcher being arranged in a spatial plane, which the light beam and the surface normal to the crucible surface of the source crucible and/or to the source surface of the source material span, and at a section of the chamber wall disposed opposite the coupling-in section in accordance with the angle of incidence.
21. The coating apparatus in accordance with embodiment 1,
   wherein the source holder has two or more source materials, with each source material being able to be heated and thermally evaporated and/or sublimated by a separate light beam of laser light.
22. The coating apparatus in accordance with embodiment 21,
   wherein the coupling-in apparatus has a common coupling-in section for conducting at least two of the separate light beams into the process volume.
22. The coating apparatus in accordance with embodiment 21,
   wherein the coupling-in apparatus has at least two separate coupling-in sections for conducting a respective at least one of the separate light beams into the process volume.
24. The coating apparatus in accordance with embodiment 1,
   wherein at least one of the light beams has a focal area, with, in the focal area, the light beam having a minimum extent perpendicular to a light direction of the light beam, with the focal area further being arranged in the process volume between the coupling-in section and the corresponding source material or the corresponding source crucible.
25. The coating apparatus in accordance with embodiment 24,
   wherein the focal areas of at least two of the light beams overlap.
26. The coating apparatus in accordance with embodiment 24,
   wherein the process chamber has at least one heating laser aperture having an aperture opening, with the heating laser aperture being arranged in the process volume such that the focal area of at least one of the light beams coincides or at least substantially coincides with the aperture opening.
27. The coating apparatus in accordance with embodiment 26,
   wherein the aperture opening is formed in the heating laser aperture by the laser light of the source heating laser.
28. The coating apparatus in accordance with embodiment 1,
   wherein the process chamber has at least one thermocouple for determining a temperature of the at least one source material and/or of the corresponding source crucible.
29. The coating apparatus in accordance with embodiment 1,
   wherein the coupling-in apparatus has at least one further coupling-in section in the chamber wall for conducting laser light of a substrate heating laser into the process volume, with the laser light at least sectionally being present as a light beam in the process volume and the substrate material of the substrate being heatable by the laser light.
30. The coating apparatus in accordance with embodiment 1,
   wherein the gas system has a process gas supply for supplying a process gas into the process volume and a pump system for generating an underpressure in the process volume, with the pump system comprising a magnetically levitated turbopump.
31. A process chamber for a coating apparatus for coating a substrate of a substrate material with at least one material layer of a layer material,
   wherein the process chamber is configured for a use in a coating apparatus in accordance with embodiment 1.
32. A method of coating a substrate of a substrate material with at least one material layer of a layer material in a coating apparatus in accordance with embodiment 1,
   wherein a source material is used for at least partly providing the layer material, said source material being heated and being thermally evaporated and/or sublimated below a plasma generation threshold of the source material by a continuous or at least substantially continuous laser light of a source heating laser.
33. The method in accordance with embodiment 32,
   wherein the source material is directly heated and thermally evaporated and/or sublimated by the laser light by a direct irradiation of the laser light onto a source surface of the source material.
34. The method in accordance with embodiment 32,
   wherein the substrate material of the substrate is heated by laser light of a substrate heating laser.
35. The method in accordance with embodiment 32
   wherein a coating atmosphere having a pressure between 10⁻¹⁰ mbar and 1 mbar is provided in the process volume by the gas system of the coating apparatus.
36. The method in accordance with embodiment 32,
   wherein a coating atmosphere having a gaseous substance adapted to the layer material of the material layer as the process gas is provided in the process volume by the gas system of the coating apparatus.
37. The method in accordance with embodiment 32,
   wherein an oxide having a perovskite structure is produced as the layer material, the oxide comprising a first metal element and a second metal element, with the first metal element and the second metal element being provided as the source material and molecular oxygen and/or ozone being used as the process gas in the coating atmosphere.
38. A substrate coated with at least one material layer, comprising the substrate of a substrate material that is coated with at least one material layer of a layer material, wherein the substrate coated with at least one material layer is produced in a coating apparatus in accordance with embodiment 1.

The present disclosure also relates to the following second set of enumerated embodiments:
1. A coating apparatus for coating a substrate of a substrate material with at least one material layer of a layer material, said coating apparatus comprising a process chamber having a process volume for receiving a substrate holder for arranging the substrate, wherein the substrate holder is arranged in a fixed position in the process volume such that the substrate holder can furthermore be provided rotatable and/or movable essentially in a plane normal to the deposition direction as a whole,
   wherein the process chamber has a chamber wall for at least substantially completely enclosing the process volume; a gas system connected in a fluid-communicating manner to the process volume for generating a coating atmosphere in the process volume; and a source holder arranged in the process volume and having at least one source material, wherein the source holder and the substrate holder are further arranged relative to one another such that thermally evaporated and/or sublimated source material can be deposited on the substrate for an at least partial formation of the layer material of the material layer, said coating apparatus further comprising a source heating laser,
   wherein the source heating laser is configured to provide a continuous or at least substantially continuous separate beam of laser light and the process chamber has a coupling-in apparatus having at least one coupling-in section in the chamber wall for conducting laser light of a source heating laser into the process volume for thermally evaporating and/or sublimating the at least one source material below a plasma generation threshold,
   wherein the process chamber comprises an airtight sealable lock with a lock volume, wherein the lock comprises a first lock door sealable against the process volume and a second lock door sealable against the environment, the process chamber further comprising an exchange mechanism for exchanging the at least one source material, wherein the exchange mechanism is constructed to operate within the process volume and to grab and move the at least one source material between the source holder and the lock volume.
2. The coating apparatus in accordance with claim 1,
   wherein the exchange mechanism is arranged within the lock volume.
3. The coating apparatus in accordance with claim 1,
   wherein the lock comprises a divider for dividing the lock volume a first compartment and a second compartment sealable to each other by the divider,
   wherein the first compartment extends between the divider and the first lock door, and the second compartment extends between the divider and the second lock door.
4. The coating apparatus in accordance with embodiment 1,
   wherein the lock comprises a source holding structure arranged in the lock volume,
   wherein the source holding structure is constructed to receive the at least one source material placed in the lock volume by the exchange mechanism.
5. The coating apparatus in accordance with embodiment 1,
   wherein the exchange mechanism is constructed to grab and move all of the at least one source materials simultaneously.
6. The coating apparatus in accordance with embodiment 1,
   wherein the exchange mechanism is constructed to also grab and move the substrate between the substrate holder and the lock volume.
7. The coating apparatus in accordance with embodiment 6,
   wherein the lock comprises a substrate holding structure arranged in the lock volume, wherein the substrate holding structure is constructed to receive the substrate placed in the lock volume by the exchange mechanism.
8. The coating apparatus in accordance with embodiment 1,
   wherein the process chamber comprises a monolithic chamber body providing the whole chamber wall.
9. The coating apparatus in accordance with embodiment 1,
   wherein the chamber body consists of aluminum or of an aluminum alloy.
10. The coating apparatus in accordance with embodiment 1,
   wherein the process chamber comprises cooling means for a fluid cooling of the process volume.
11. The coating apparatus in accordance with embodiment 10,
   wherein the cooling means comprise coolant ducts, wherein further the coolant ducts are at least partly integrated in the chamber body.
12. The coating apparatus in accordance with embodiment 1,
   wherein each of the at least one source materials is provided as a pure chemical element.
13. The coating apparatus in accordance with embodiment 12,
   wherein the layer material is a compound comprising two or more chemical elements, wherein at least one of the two or more chemical elements originates from one of the at least one source materials.
14. The coating apparatus in accordance with embodiment 13,
   wherein the coating atmosphere comprises a reaction gas, wherein at least one of the two or more chemical elements of the layer material originates from the reaction gas.
15. The coating apparatus in accordance with embodiment 13,
   a surface of the substrate is prepared such that the compound is formed only surface of the substrate.
16. The coating apparatus in accordance with embodiment 15,
   wherein the apparatus comprises a substrate heating laser for heating the substrate,
   wherein the substrate heating laser is constructed for heating the substrate such that at least one chemical element of the compound forming the layer material desorbs from the substrate if not incorporated into the compound forming the layer material.
17. The coating apparatus in accordance with embodiment 1,
   wherein the source material can be directly heated and thermally evaporated and/or sublimated by the laser light by a direct irradiation of the laser light onto a source surface of the source material.
18. The coating apparatus in accordance with embodiment 1,
   wherein the light beam encloses an angle of incidence between 0° and 90° with a surface normal to a crucible surface of the source crucible having source material and/or with a surface normal to a source surface of the source material.
19. The coating apparatus in accordance with embodiment 1,
   wherein at least one of an intensity and a wavelength of the laser light is adapted to the corresponding source material.
20. The coating apparatus in accordance with embodiment 1,
   wherein the process chamber has, at an inner side of the chamber wall, at least one beam catcher for at least partly absorbing reflected laser light, with the beam catcher being arranged in a spatial plane, which the light beam and the surface normal to the crucible surface of the source crucible and/or to the source surface of the source material span, and at a section of the chamber wall disposed opposite the coupling-in section in accordance with the angle of incidence.
21. The coating apparatus in accordance with embodiment 1,
   wherein the source holder has two or more source materials, with each source material being able to be heated and thermally evaporated and/or sublimated by a separate light beam of laser light.
22. The coating apparatus in accordance with embodiment 21,
   wherein the coupling-in apparatus has a common coupling-in section for conducting at least two of the separate light beams into the process volume.
23. The coating apparatus in accordance with embodiment 21,
   wherein the coupling-in apparatus has at least two separate coupling-in sections for conducting a respective at least one of the separate light beams into the process volume.
24. The coating apparatus in accordance with embodiment 1,
   wherein at least one of the light beams has a focal area, with, in the focal area, the light beam having a minimum extent perpendicular to a light direction of the light beam, with the focal area further being arranged in the process volume between the coupling-in section and the corresponding source material or the corresponding source crucible.
25. The coating apparatus in accordance with embodiment 24,
   wherein the focal areas of at least two of the light beams overlap.
26. The coating apparatus in accordance with embodiment 24,
   wherein the process chamber has at least one heating laser aperture having an aperture opening, with the heating laser aperture being arranged in the process volume such that the focal area of at least one of the light beams coincides or at least substantially coincides with the aperture opening.
27. The coating apparatus in accordance with embodiment 26,
   wherein the aperture opening is formed in the heating laser aperture by the laser light of the source heating laser.
28. The coating apparatus in accordance with embodiment 1,
   wherein the process chamber has at least one thermocouple for determining a temperature of the at least one source material and/or of the corresponding source crucible.
29. The coating apparatus in accordance with embodiment 1,
   wherein the coupling-in apparatus has at least one further coupling-in section in the chamber wall for conducting laser light of a substrate heating laser into the process volume, with the laser light at least sectionally being present as a light beam in the process volume and the substrate material of the substrate being heatable by the laser light.
30. The coating apparatus in accordance with embodiment 1,
   wherein the gas system has a process gas supply for supplying a process gas into the process volume and a pump system for generating an underpressure in the process volume, with the pump system comprising a magnetically levitated turbopump.
31. A process chamber for a coating apparatus for coating a substrate of a substrate material with at least one material layer of a layer material,
   wherein the process chamber is configured for a use in a coating apparatus in accordance with embodiment 1.
32. A method of coating a substrate of a substrate material with at least one material layer of a layer material in a coating apparatus in accordance with embodiment 1,
   wherein a source material is used for at least partly providing the layer material, said source material being heated and being thermally evaporated and/or sublimated below a plasma generation threshold of the source material by a continuous or at least substantially continuous laser light of a source heating laser.
33. The method in accordance with embodiment 32,
   wherein the source material is directly heated and thermally evaporated and/or sublimated by the laser light by a direct irradiation of the laser light onto a source surface of the source material.
34. The method in accordance with embodiment 32,
   wherein the substrate material of the substrate is heated by laser light of a substrate heating laser.
35. The method in accordance with embodiment 32,
   wherein a coating atmosphere having a pressure between 10⁻¹⁰ mbar and 1 mbar is provided in the process volume by the gas system of the coating apparatus.
36. The method in accordance with embodiment 32,
   wherein a coating atmosphere having a gaseous substance adapted to the layer material of the material layer as the process gas is provided in the process volume by the gas system of the coating apparatus.
37. The method in accordance with embodiment 32,
   wherein an oxide having a perovskite structure is produced as the layer material, the oxide comprising a first metal element and a second metal element, with the first metal element and the second metal element being provided as the source material and molecular oxygen and/or ozone being used as the process gas in the coating atmosphere.
38. A substrate coated with at least one material layer, comprising the substrate of a substrate material that is coated with at least one material layer of a layer material,
   wherein the substrate coated with at least one material layer is produced in a coating apparatus in accordance with embodiment 1.

### REFERENCE NUMERAL LIST

1 coating apparatus
10 process chamber
12 process volume
14 chamber wall
16 inner side
18 coupling-in apparatus
20 coupling-in section
22 beam catcher
24 shutter cover
30 gas system
32 process gas supply
34 pump system
36 turbopump
40 coating atmosphere
42 process gas
50 substrate holder
52 substrate
54 substrate material
56 material layer
58 layer material
60 source holder
62 source crucible
64 crucible surface
66 source material
68 source surface
70 thermocouple
72 measurement position
74 release position
76 fastening section
80 source heating laser
82 substrate heating laser
84 laser light
86 light beam
88 light direction
90 focal area
100 heating laser aperture
102 aperture opening
110 angle of incidence
112 surface normal
114 spatial plane
200 sealable lock
202 lock volume
204 first lock door
206 second lock door
210 exchange mechanism
220 source holding structure
230 substrate holding structure
240 divider
242 first compartment
244 second compartment

1. A coating apparatus for coating a substrate of a substrate material with at least one material layer of a layer material, said coating apparatus comprising a process chamber having a process volume for receiving a substrate holder for arranging the substrate, wherein the substrate holder is arranged in a fixed position in the process volume such that the substrate holder can furthermore be provided rotatable and/or movable essentially in a plane normal to the deposition direction as a whole,
wherein the process chamber has a chamber wall for at least substantially completely enclosing the process volume; a gas system connected in a fluid-communicating manner to the process volume for generating a coating atmosphere in the process volume; and a source holder arranged in the process volume and providing at least one source material, wherein each of the at least one source materials is provided as a pure chemical element, said coating apparatus further comprising a source heating laser,
wherein the source heating laser is configured to provide a continuous or at least substantially continuous separate beam of laser light for each of the at least one elemental source materials and the process chamber has a coupling-in apparatus having at least one coupling-in section in the chamber wall for conducting the separate beams of laser light of the source heating laser into the process volume for thermally evaporating and/or sublimating each of the elemental source materials below a plasma generation threshold,
wherein the source holder and the substrate holder are further arranged relative to one another such that thermally evaporated and/or sublimated source material originating from the at least one source material can be deposited on the substrate for an at least partial formation of the layer material of the material layer.

2. The coating apparatus in accordance with claim 1,
wherein the layer material is a compound comprising two or more chemical elements, wherein at least one of the two or more chemical elements originates from one of the at least one source materials.

3. The coating apparatus in accordance with claim 2,
wherein the coating atmosphere comprises a reaction gas, wherein at least one of the two or more chemical elements of the layer material originates from the reaction gas.

4. The coating apparatus in accordance with claim 2,
wherein a surface of the substrate is prepared such that the compound is formed only on the surface of the substrate.

5. The coating apparatus in accordance with claim 4,
wherein the apparatus comprises a substrate heating laser for heating the substrate,
wherein the substrate heating laser is constructed for heating the substrate such that at least one chemical element of the compound forming the layer material desorbs from the substrate if not incorporated into the compound forming the layer material.

6. The coating apparatus in accordance with claim 1,
wherein the process chamber comprises a monolithic chamber body providing the whole chamber wall.

7. The coating apparatus in accordance with claim 6,
wherein the chamber body consists of aluminum or of an aluminum alloy.

8. The coating apparatus in accordance with claim 6,
wherein the process chamber comprises cooling means for a fluid cooling of the process volume.

9. The coating apparatus in accordance with claim 8,
wherein the cooling means comprise coolant ducts, wherein further the coolant ducts are at least partly integrated in the chamber body.

10. The coating apparatus in accordance with claim 1,
wherein the process chamber comprises an airtight sealable lock with a lock volume, wherein the lock comprises a first lock door sealable against the process volume and a second lock door sealable against the environment, the process chamber further comprising an exchange mechanism for exchanging the at least one source material, wherein the exchange mechanism is constructed to operate within the process volume and to grab and move the at least one source material between the source holder and the lock volume.

11. The coating apparatus in accordance with claim 10,
wherein the exchange mechanism is arranged within the lock volume.

12. The coating apparatus in accordance with claim 10,
wherein the lock comprises a divider for dividing the lock volume a first compartment and a second compartment sealable to each other by the divider,
wherein the first compartment extends between the divider and the first lock door, and the second compartment extends between the divider and the second lock door.

13. The coating apparatus in accordance with claim 10,
wherein the lock comprises a source holding structure arranged in the lock volume,
wherein the source holding structure is constructed to receive the at least one source material placed in the lock volume by the exchange mechanism.

14. The coating apparatus in accordance with claim 10,
wherein the exchange mechanism is constructed to grab and move all of the at least one source materials simultaneously.

15. The coating apparatus in accordance with claim 10,
wherein the exchange mechanism is constructed to also grab and move the substrate between the substrate holder and the lock volume.

16. The coating apparatus in accordance with claim 15,
wherein the lock comprises a substrate holding structure arranged in the lock volume, wherein the substrate holding structure is constructed to receive the substrate placed in the lock volume by the exchange mechanism.

17. The coating apparatus in accordance with claim 1,
wherein the source material can be directly heated and thermally evaporated and/or sublimated by the laser light by a direct irradiation of the laser light onto a source surface of the source material.

18. The coating apparatus in accordance with claim 1,
wherein the light beam encloses an angle of incidence between 0° and 90° with a surface normal to a crucible surface of the source crucible having source material and/or with a surface normal to a source surface of the source material.

19. The coating apparatus in accordance with claim 1,
wherein at least one of an intensity and a wavelength of the laser light is adapted to the corresponding source material.

20. The coating apparatus in accordance with claim 1,
wherein the process chamber has, at an inner side of the chamber wall, at least one beam catcher for at least partly absorbing reflected laser light, with the beam catcher being arranged in a spatial plane, which the light beam and the surface normal to the crucible surface of the source crucible and/or to the source surface of the source material span, and at a section of the chamber wall disposed opposite the coupling-in section in accordance with the angle of incidence.

21. The coating apparatus in accordance with claim 1,
wherein the source holder has two or more source materials, with each source material being able to be heated and thermally evaporated and/or sublimated by a separate light beam of laser light.

22. The coating apparatus in accordance with claim 21,
wherein the coupling-in apparatus has a common coupling-in section for conducting at least two of the separate light beams into the process volume.

23. The coating apparatus in accordance with claim 21,
wherein the coupling-in apparatus has at least two separate coupling-in sections for conducting a respective at least one of the separate light beams into the process volume.

24. The coating apparatus in accordance with claim 1,
wherein at least one of the light beams has a focal area, with, in the focal area, the light beam having a minimum extent perpendicular to a light direction of the light beam, with the focal area further being arranged in the process volume between the coupling-in section and the corresponding source material or the corresponding source crucible.

25. The coating apparatus in accordance with claim 24,
wherein the focal areas of at least two of the light beams overlap.

26. The coating apparatus in accordance with claim 24,
wherein the process chamber has at least one heating laser aperture having an aperture opening, with the heating laser aperture being arranged in the process volume such that the focal area of at least one of the light beams coincides or at least substantially coincides with the aperture opening.

27. The coating apparatus in accordance with claim 26,
wherein the aperture opening is formed in the heating laser aperture by the laser light of the source heating laser.

28. The coating apparatus in accordance with claim 1,
wherein the process chamber has at least one thermocouple for determining a temperature of the at least one source material and/or of the corresponding source crucible.

29. The coating apparatus in accordance with claim 1,
wherein the coupling-in apparatus has at least one further coupling-in section in the chamber wall for conducting laser light of a substrate heating laser into the process volume, with the laser light at least sectionally being present as a light beam in the process volume and the substrate material of the substrate being heatable by the laser light.

30. The coating apparatus in accordance with claim 1,
wherein the gas system has a process gas supply for supplying a process gas into the process volume and a pump system for generating an underpressure in the process volume, with the pump system comprising a magnetically levitated turbopump.

31. A process chamber for a coating apparatus for coating a substrate of a substrate material with at least one material layer of a layer material,
wherein the process chamber is configured for a use in a coating apparatus in accordance with claim 1.

32. A method of coating a substrate of a substrate material with at least one material layer of a layer material in a coating apparatus in accordance with claim 1,
wherein a source material is used for at least partly providing the layer material, said source material being heated and being thermally evaporated and/or sublimated below a plasma generation threshold of the source material by a continuous or at least substantially continuous laser light of a source heating laser.

33. The method in accordance with claim 32,
wherein the source material is directly heated and thermally evaporated and/or sublimated by the laser light by a direct irradiation of the laser light onto a source surface of the source material.

34. The method in accordance with claim 32,
wherein the substrate material of the substrate is heated by laser light of a substrate heating laser.

35. The method in accordance with claim 32,
wherein a coating atmosphere having a pressure between 10⁻¹⁰ mbar and 1 mbar is provided in the process volume by the gas system of the coating apparatus.

36. The method in accordance with claim 32,
wherein a coating atmosphere having a gaseous substance adapted to the layer material of the material layer as the process gas is provided in the process volume by the gas system of the coating apparatus.

37. The method in accordance with claim 32,
wherein an oxide having a perovskite structure is produced as the layer material, the oxide comprising a first metal element and a second metal element, with the first metal element and the second metal element being provided as the source material and molecular oxygen and/or ozone being used as the process gas in the coating atmosphere.

38. A substrate coated with at least one material layer, comprising the substrate of a substrate material that is coated with at least one material layer of a layer material, wherein the substrate coated with at least one material layer is produced in a coating apparatus in accordance with claim 1.
